(19) United States
(12) Patent Application Publication
(10) Pub. No.: US 2013/0081683 A1
(43) Pub. Date: Apr. 4, 2013

(54) PHOTOELECTRIC CONVERSION ELEMENT AND METHOD OF PRODUCING THE SAME

(71) Applicants: Kumi MASUNAGA, Tokyo (JP); Akira FUJIMOTO, Tokyo (JP); Eishi TSUTSUMI, Tokyo (JP); Koji ASAKAWA, Tokyo (JP); Tsutomu NAKANISHI, Tokyo (JP); Hideyuki NISHIZAWA, Tokyo (JP); Ryota KITAGAWA, Tokyo (JP)

(72) Inventors: Kumi MASUNAGA, Tokyo (JP); Akira FUJIMOTO, Tokyo (JP); Eishi TSUTSUMI, Tokyo (JP); Koji ASAKAWA, Tokyo (JP); Tsutomu NAKANISHI, Tokyo (JP); Hideyuki NISHIZAWA, Tokyo (JP); Ryota KITAGAWA, Tokyo (JP)

(21) Appl. No.: 13/628,738

(22) Filed: Sep. 27, 2012

Related U.S. Application Data
(63) Continuation of application No. PCT/JP2010/002457, filed on Apr. 2, 2010.

(51) Int. Cl. H01L 31/06; H01L 31/18

(52) U.S. Cl. CPC H01L 31/06; H01L 31/18
USPC 136/255; 438/57

(57) ABSTRACT

The present invention provides a photoelectric conversion element having high efficiency in propagating carrier excitation by use of enhanced electric fields. The photoelectric conversion element comprises a photoelectric conversion layer including two or more laminated semiconductor layers placed between two electrode layers, and is characterized by having an electric field enhancing layer placed between the semiconductor layers in the photoelectric conversion layer. The electric field enhancing layer is provided with a metal-made minute structure, and the minute structure is, for example, a porous membrane or a group of nano-objects such as very small spheres.

### CROSS REFERENCE TO RELATED APPLICATIONS

This application is a continuation of International Application No. PCT/JP2010/02457, filed on Apr. 2, 2010, the entire contents of which is hereby incorporated by reference.

### TECHNICAL FIELD

This invention relates to a photoelectric conversion element and a method of producing that.

### BACKGROUD ART

As a means for improving efficiency of solar cells, incident sunlight may be converted into other energy form suitable for photoelectric conversion. For example, there is a method in which plasmon resonance is caused by use of a nano-structure to generate enhanced electric fields and thereby to propagate carrier excitation. The “plasmon resonance” is a phenomenon in which oscillating waves of massive electrons occur on metal surfaces, and is known to accompany enhanced electromagnetic fields that activate carrier generation.

Actually, Patent document 1 proposes a solar cell whose photosensitive layer comprises a metal-made nano-structure as a main constituting element so that surface plasmons can be utilized for light absorption.

### PRIOR ART DOCUMENTS

[Patent document 1]WO2007/118815

### DISCLOSURE OF INVENTION

### Problem to be Solved by the Invention

However, there is still a demand for further improving the photoelectric conversion efficiency of photoelectric conversion elements.

Accordingly, it is an object of the present invention to provide a photoelectric conversion element having high efficiency in propagating carrier excitation by use of enhanced electric fields.

### Means for Solving Problem

The present invention resides in a photoelectric conversion element comprising
a photoelectric conversion layer which comprises two electrode layers and two or more laminated semiconductor layers placed between said two electrode layers, and
a metal-made porous membrane placed between adjacent two of said semiconductor layers; wherein
said porous membrane has plural openings bored though said membrane,
each of said openings occupies an area of 80 nm² to 0.8 μm² inclusive on average, and
said porous membrane has a thickness of 2 nm to 200 nm inclusive.

The present invention also resides in a photo-electric conversion element comprising
a photoelectric conversion layer which comprises two electrode layers and two or more laminated semiconductor layers placed between said two electrode layers, and
a layer which has plural metal-made nano-objects and which is placed between adjacent two of said semiconductor layers; wherein
each of said nano-objects has a volume of 4 nm³ to 0.52 μm³ inclusive on average, and
the average distance between adjacent two of said nano-objects is in the range of 1 nm to 1 μm inclusive.

The present invention further resides in a method of producing the photoelectric conversion element according to claim 1 and 4, comprising the steps of
forming at least one semiconductor layer,
forming a metal membrane on said semiconductor layer,
preparing a stamper whose surface has a fine relief pattern corresponding to the shape of openings intended to be formed,
transferring a resist pattern onto at least a part of said metal membrane by use of said stamper,
forming a pattern on said metal membrane by use of said resist pattern as an etching mask, and
forming at least one semiconductor layer on said metal membrane provided with the pattern.

### Effect of the Invention

The present invention enables to obtain a photo-electric conversion element having high efficiency in propagating carrier excitation by use of enhanced electric fields.

### BRIEF DESCRIPTION OF THE DRAWINGS

FIG. 1 shows conceptual drawings illustrating a solar cell according to an embodiment of the present invention.

FIG. 2 shows conceptual drawings illustrating the working principle of a solar cell according to an embodiment of the present invention.

FIG. 3 shows conceptual sketches of metal-made minute structures usable in a solar cell according to an embodiment of the present invention.

FIG. 4 shows the results of simulation of electric field-enhancement effect.

FIG. 5 shows the results of simulation of electric field-enhancement effect.

FIG. 6 shows the results of simulation of electric field-enhancement effect.

FIG. 7 shows schematic drawings illustrating densities of minute structures.

FIG. 8 shows schematic sectional views illustrating a method of producing a solar cell according to an embodiment of the present invention.

FIG. 9 shows schematic sectional views illustrating a method of producing a solar cell according to an embodiment of the present invention.

FIG. 10 shows schematic sectional views illustrating a method of producing a solar cell according to an embodiment of the present invention.

FIG. 11 shows schematic sectional views illustrating a method of producing a solar cell according to an embodiment of the present invention.

FIG. 12 shows schematic sectional views illustrating a method of producing a solar cell according to an embodiment of the present invention.

FIG. 13 shows schematic sectional views illustrating a method of producing a solar cell according to an embodiment of the present invention.

FIG. 14 shows schematic sectional views illustrating a method of producing a solar cell according to an embodiment of the present invention.

FIG. 15 shows schematic sectional views illustrating a method of producing a solar cell according to an embodiment of the present invention.

FIG. 16 shows schematic sectional views illustrating a method of producing a solar cell according to an embodiment of the present invention.

FIG. 17 shows schematic sectional views illustrating a method of producing a solar cell according to an embodiment of the present invention.

### BEST MODE FOR CARRYING OUT THE INVENTION

The photoelectric conversion element of the present invention comprises a metal-made minute structure placed between semiconductor layers. The present inventors have found that electric fields can be enhanced to improve the conversion efficiency of the photoelectric conversion element if the minute structure is a porous membrane having a thickness of 2 nm to 200 nm inclusive and also having fine openings each of which occupies an area of 80 nm² to 0.8 μm² inclusive on average.

In addition, the present inventors have further found that electric fields can be also enhanced to improve the conversion efficiency of the photoelectric conversion element if the minute structure is a group of nano-objects each of which has a volume of 4 nm³ to 0.52 μm³ inclusive on average and the average distance between adjacent two of which is in the range of 1 nm to 1 μm inclusive.

The present invention will be described below with reference to the attached drawings.

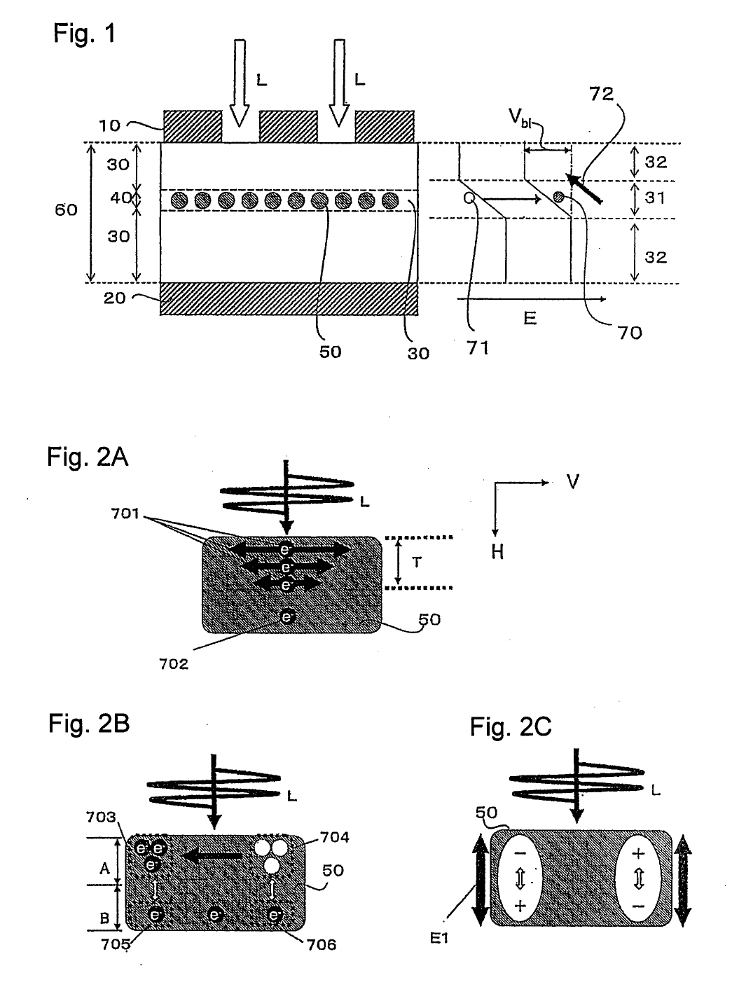

First, the principle of the present invention will be explained in detail by describing, by way of example, a solar cell, which is a kind of photoelectric conversion element. As shown in the schematic sectional view of the left drawing in FIG. 1, the solar cell according to an embodiment of the present invention comprises a light-incident side electrode 10, a counter electrode 20 on the opposite side, and a photoelectric conversion layer 60 placed between them. The photoelectric conversion layer 60 comprises semiconductor layers 30 and a (electric field enhancing) layer 40 provided with a metal-made minute structure 50 and placed between the semiconductor layers 30.

Whether the minute structure 50 is a porous membrane or a group of nano-objects, the sectional view can be schematically shown as in the left drawing of FIG. 1. In the case where the minute structure is a porous membrane, the openings thereof are filled with the semiconductor of the layers 30. On the other hand, if the minute structure is a group of nano-objects, gaps among them are filled with the semiconductor of the layers 30.

When incident sunlight L comes onto the (light-receiving) face of the semiconductor layer 30 on the side of the electrode 10, it generates pairs of electrons 70 and holes 71 in the photoelectric conversion layer 60 and consequently an electric current flows between the electrodes on both sides (namely, between the light-incident side electrode 10 and the counter electrode layer 20).

The right drawing of FIG. 1 is an energy band diagram indicating energy levels at the positions corresponding to those shown in the left drawing of the solar cell. The energy band diagram schematically illustrates a process in which pairs of electrons 70 and holes 71 are generated by light absorption and then the carriers move to cause a current. In FIG. 1, the flow of electrons is represented by an arrow 72.

In the photoelectric conversion layer 60, there is an area where pairs of electrons 70 and holes 71 can be generated by light absorption and then the carriers can be effectively collected. That area is referred to as a “photoactive layer” 31. The photoactive layer 31 includes an area where the built-in electric field V_{bi} is formed as shown in the energy band diagram. Specifically, for example, the photoactive layer 31 in a pn junction is an area including the depletion layer and the periphery thereof. The “periphery” here means an area within the range of about the minority carrier diffusion length from the edges of the depletion layer. On the other hand, the photoactive layer 31 in a pin junction is an area of the i layer. The area other than the photoactive layer 31 in the photoelectric conversion layer 60 is referred to as a “bulk semiconductor layer” 32. Accordingly, the semiconductor layers 30 include areas of the photoactive layer 31 and the bulk semiconductor layer 32. In FIG. 1, the electric field enhancing layer 40 is at least partly included in the photoactive layer 31. In contrast, as for the semiconductor layers 30, a part near to the electric field enhancing layer 40 is included in the photoactive layer 31 while the other part is included in the bulk semiconductor layer 32.

The solar cell according to an embodiment of the present invention is characterized in that the photo-electric conversion layer 60 comprises the electric field enhancing layer 40 provided with the above-described minute structure 50.

### (Principle)

As described above, the present inventors have found that the solar cell having the structure shown in FIG. 1 enables to increase the electric current more than expected from the amount of light received by the semiconductor layer 30.

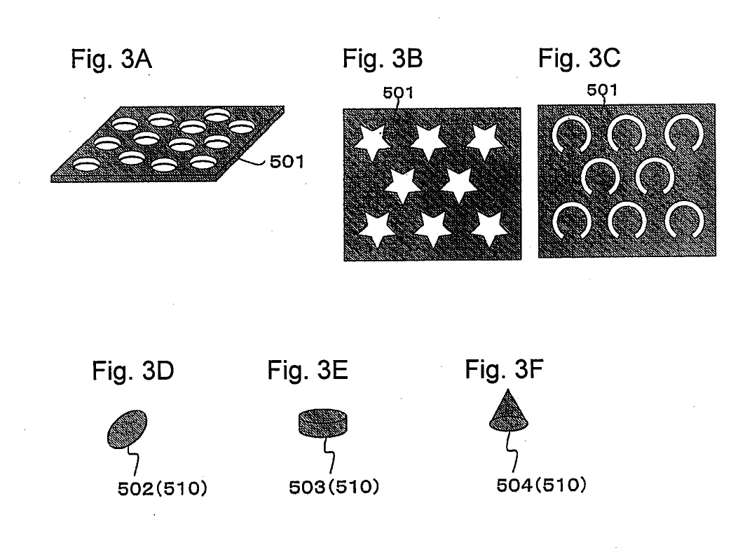

FIG. 2 shows conceptual drawings illustrating the working principle. The drawings of FIG. 2 are enlarged sectional views showing a part of the minute structure 50 shown in FIG. 1. The above phenomenon can be presumed to be caused by the following mechanism. First, it is already known that, when the metal-made minute structure 50 in the electric field enhancing layer 40 are exposed to light L, surface plasmons are excited provided that the minute structure 50 has a dimension corresponding to the wavelength of the incident light. As shown in FIG. 2(a), when the electric field enhancing layer 40 receives light L, free electrons in the minute structure 50 are induced to oscillate perpendicularly (in the V direction) to the direction of light propagation. However, the oscillation of free electrons is not uniform in the thickness direction. The nearer to the surface irradiated with the light the free electrons (701) are positioned, the more easily they are oscillated. In contrast, the free electrons (702) positioned on the side opposite to the irradiated side are hard to be oscillated because the electromagnetic waves cannot reach to the opposite side sufficiently. This tendency is referred to as “skin effect”, and the depth to which the electro-magnetic waves can reach is referred to as “skin depth” T.

FIG. 2(b) schematically shows a momentary phase of electrons oscillated by the incident light coming into the metal-made minute structure 50. In the end part A of the minute structure 50 on the upper side (light-incident side), free electrons are oscillated to form an area 703 where the electrons are densely localized and an area 704 where they are thinly populated. On the other hand, in the end part B on the lower side (side opposite to the light-incident side), the free electrons are not oscillated and accordingly the electrons are not localized. As a result, in the minute structure 50, density differences of the free electrons are formed between the upper end part A (703, 704) and the lower end part B (705, 706). Specifically, the free electron densities in 703 and 704 are different from those in 705 and 706, respectively.

Consequently, as shown in FIG. 2(c), local alternating electric fields (local electric fields) E1 are generated near the edges of the minute structure 50. The local electric fields E1 oscillate parallel (in H direction) to the direction of light propagation, and are several hundred times as strong as the electric field initially generated by the incident light L. In addition, those enhanced electric fields E1 promote generation of pairs of electrons 70 and holes 71. Here, the term “edge of the minute structure 50” means the boundary between the minute structure 50 and the semiconductor layer 30 in the electric field enhancing layer 40. When the free electrons in the minute structure 50 are oscillated by the incident light, the oscillation is broken at the boundary. Hereinafter, the terms “local electric field” and “enhanced electric field” are used in the same meaning.

The local electric fields E1 do not extend largely and they spread over at most within the range of about the dimension of the minute structure 50. Accordingly, in the case where the minute structure 50 capable of generating the local electric fields E1 is positioned outside of the semiconductor layer 30, the local electric fields E1 can contribute only to carrier generation on the surface of the semiconductor layer 30 even if they are generated. In contrast, the present invention provides a minute structure 50 in such a shape as propagates carrier excitation inside of the semiconductor layer by use of the enhanced electric fields, and thereby enables to utilize the local electric fields E1 effectively for carrier generation.

### (Definition of Metal-Made Minute Structure)

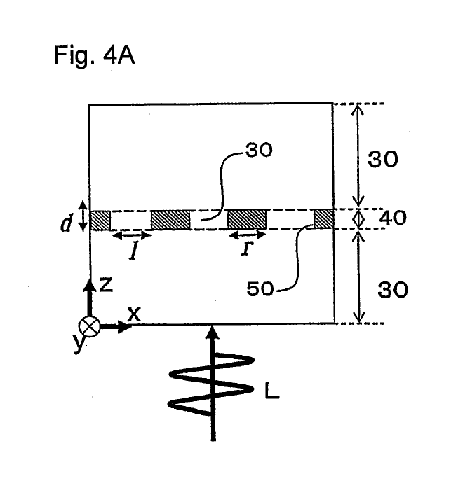

The metal-made minute structure 50 is a porous membrane 501. The porous membrane is obtained, for example, by boring a continuous metal-made membrane to form openings shown in FIG. 3(a), (b) or (c). FIG. 3(a) is a sketch of an example of the porous membrane 501, and FIG. 3(b) and (c) are top views of other examples thereof.

Otherwise, the metal-made minute structure 50 is a group of nano-objects 510. Each nano-object 510 is, for example, a minute sphere 502 (FIG. 3(d)), a minute pillar 503 (FIG. 3(e)) or a minute cone 504 (FIG. 3(f)).

The structure like that shown in FIG. 3(a), (b) or (c) is referred to as a “porous membrane 501”, and the structure like that shown in FIG. 3(d), (e) or (f) is referred to as a “nano-object 510”.

### (Preferred Metal-made Minute Structure)

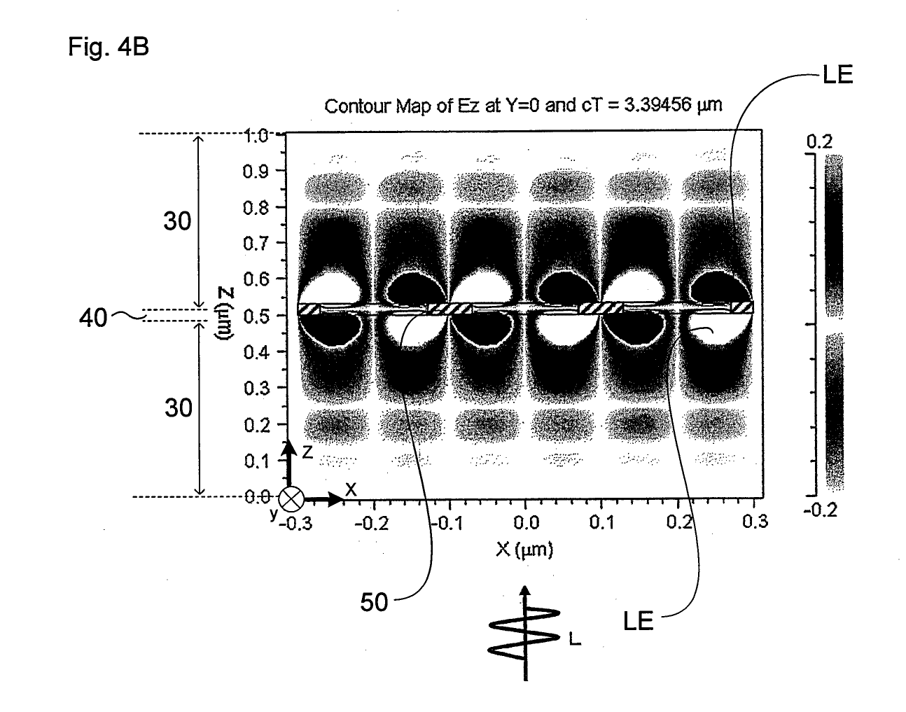

The following describes strong local electric fields generated near the edges of the minute structure 50. The electric fields were simulated according to the FDTD (finite difference time domain) method under the assumption that the minute structure 50 was an Al-made porous membrane 501, by way of example. The optical model adopted in the simulation was shown in FIG. 4(a), and the results of the simulation were shown in FIG. 4(b).

In the simulated model, the Al-made porous membrane 501 was placed between Si semiconductor layers 30. The Al-made porous membrane 501 was assumed to have a thickness d of 30 nm and to be provided with circular openings having a diameter l of 140 nm, and it was also assumed that adjacent two of the openings were separated by a metal area having a width (which is hereinafter often referred to as “metal width among the openings r”) of 60 nm in the Al-made porous membrane 501. The openings were filled with Si of the semiconductor layers 30, to constitute an electric field enhancing layer 40. The sectional view (in the xz plane) of the assumed model shown in FIG. 4(a) was perpendicular to the electric field enhancing layer 40. The opening diameter l and the metal width among the openings r were defined in the direction perpendicular to the propagation direction of incident light L, while the thickness d of the porous membrane 501 was in the direction parallel to the propagation direction of incident light L.

FIG. 4(b) exhibits simulated Ez electric field strength on the xz plane when the above model is exposed to incident light L (λ: 1000 nm, the propagation direction: z). The simulation results verify that Ez electric fields are enhanced at the edges of openings in the Al-made porous membrane 501 to generate local electric fields LE.

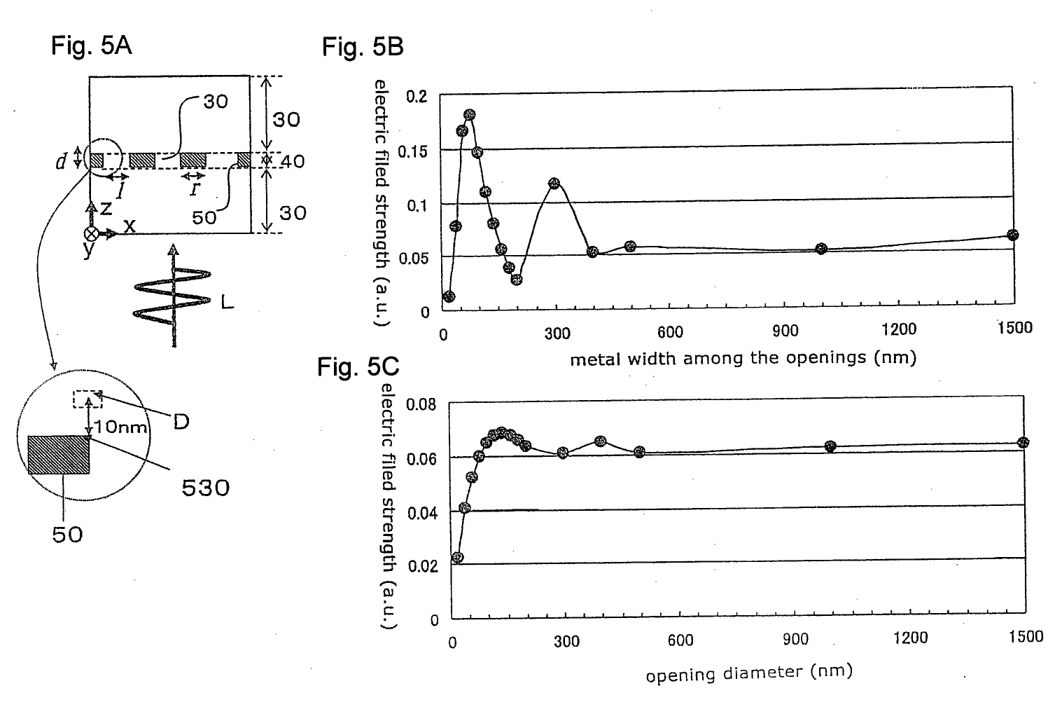

FIG. 5 shows results of other FDTD calculations carried out in the cases where the opening diameter l and the metal width among the openings r in the Al-made porous membrane 501 were variously changed in the optical model (FIG. 5(a)), which is the same as that in FIG. 4(a). FIG. 5(a) exhibits the simulated optical model structure and the point at which the local electric filed strength was calculated. FIG. 5(b) exhibits the relation between the metal width among the openings r in the Al-made porous membrane 501 and the local electric filed strength at the point D, and FIG. 5(c) exhibits the relation between the opening diameter l in the Al-made porous membrane 501 and the local electric filed strength at the point D. The “local electric filed strength” in FIG. 5 means the strength of Ez electric fields generated near the edges of openings in the Al-made porous membrane 501, and the point D was positioned 10 nm apart from the top end edge 530 of an opening in the porous membrane 501. The Ez electric fields are not induced by plane waves.

### <(1) Preferred Opening Diameter and Interval (Lower Limit)>

The results shown in FIG. 5(b) reveal that the local electric fields are generated if the metal width among the openings r is 10 nm or more in the Al-made porous membrane 501 and further that they are particularly enhanced to increase the electric field-enhancement effect if the metal width r is in the range of 20 nm to 500 nm inclusive.

Similarly, as shown in FIG. 5(c), the local electric fields are generated if the opening diameter l is 10 nm or more, that is, if each opening occupies an area of 80 nm² or more in the Al-made porous membrane 501. Further, the local electric fields are particularly enhanced to increase the electric field-enhancement effect if the opening diameter l is 20 nm to 500 nm inclusive, that is, if each opening occupies an area of 300 nm² to 0.2 μm² inclusive. It is already known that, even in the case where the openings are not circles in shape, the local electric fields are generated if each opening occupies an area of 80 nm² or more and further are particularly enhanced to increase the electric field-enhancement effect if each opening occupies an area of 300 nm² to 0.2 μm² inclusive.

### <(2) Preferred Nano-Object Size and Interval (Lower Limit)>

Similarly to the case where the minute structure 50 was a porous membrane 501, the simulation was carried out in the case where nano-objects 510 were adopted. As a result, strongly enhanced electric fields were generated if the nano-object was a sphere having a diameter r′ of 2 nm to 1 μm inclusive, namely, having a volume of 4 nm³ to 0.52 μm³ inclusive. Further, the electric field-enhancement effect was particularly strengthened if the spherical nano-object 510 had a diameter of 10 nm to 500 nm inclusive on average, namely, had a volume of 520 nm³ to 6.5×10⁻² μm³ inclusive on average. It is already known that, even in the case where the nano-object is not a sphere in shape, enhanced electric fields are strongly generated if the volume thereof is in the range of 4 nm³ to 0.52 μm³ inclusive and further are particularly strengthened enough to increase the electric field-enhancement effect if the volume thereof is in the range of 520 nm³ to 6.5×10⁻² μm³ inclusive.

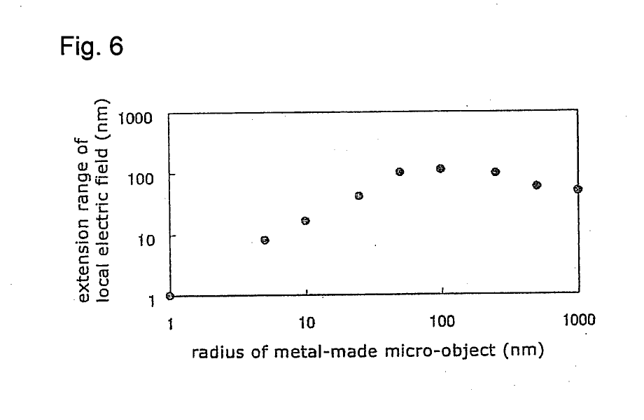

However, if the interval l′ between adjacent two of the nano-objects 510 is so short that one nano-object is positioned within the range of the local electric field generated by the other, the electric field energy may be transferred between them to cause energy loss. Accordingly, in order to utilize the enhanced electric field effectively for carrier excitation in the semiconductor layer, the interval l′ is preferably not too short. The extension range of the local electric field depends on the dimension of the nano-object 510. FIG. 6 shows the relation between the extension range of the electric field and the radius of the nano-object. In FIG. 6, the radius of the nano-object ranges from 1 nm to 100 nm, and this range corresponds to the above-described volume range of 4 nm³ to 0.52 μm³ inclusive. If the nano-object 510 has a small dimension, the local electric field extends within the range about half as short as the dimension. Specifically, if the nano-object 510 is a sphere of 1 nm radius (namely, of 4 nm³ volume), the local electric field extends within about 1 nm-range (which is as short as the radius). However, the extension range of the local electric field by no means increases in proportion to the dimension of the nano-object 510. If the nano-object 510 has a dimension larger than a particular value, the local electric field extends within at most 100 nm-range or shorter. Specifically, if the nano-object 510 is a sphere of 100 nm radius (namely, of 4×10⁻³ μm³ volume), the local electric field extends within about 100 nm-range or shorter.

In the case where the nano-object was not a sphere in shape, the local electric field extends within the range as long as about the reduced radius calculated according to the following formula (1):

reduced radius=0.62×(volume)^{1/3} (1)

provided that the nano-object has a volume of less than 4×10⁻³ μm³. In contrast, if the volume is 4×10⁻³ μm³ or more, the local electric field extends within at most 100 nm-range or shorter.

Accordingly, the interval l′ among the nano-objects is preferably not less than the above reduced radius if the nano-object has a volume of less than 4×10⁻³ μm³. If the volume is 4×10⁻³ μm³ or more, the interval l′ is preferably 100 nm or more.

### <(3) Preferred Density of Minute Structure (Upper Limits of Width and Interval)>

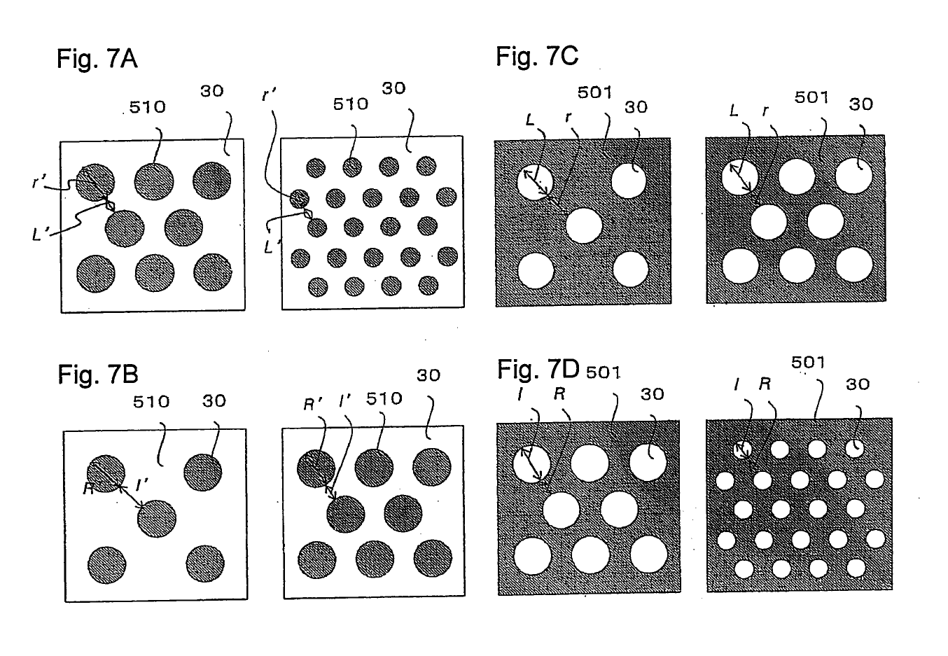

In the case where the minute structure 50 satisfies the above conditions, it preferably has edges so densely that the electric field strength per unit area can be further increased. FIG. 7 shows top views (seen from the light-incident side) of minute structures 50 usable in the electric field enhancing layer 40. Preferred minute structures will be described below by use of FIG. 7.

The case described first is where the minute structure 50 is a group of nano-objects 510 each of which is a sphere in shape and which are periodically positioned in the electric field enhancing layer 40. If the interval l′ among the nano-objects 510 is a constant value L′ as shown in FIG. 7(a), the number of the nano-objects 510 per unit area increases and hence the amount of the edges of the nano-objects 510 increases in accordance with decrease of the diameter r′ of the nano-objects 510. On the other hand, if the diameter r′ of the nano-objects 510 is a constant value R′ as shown in FIG. 7(b), the amount of the edges increases in accordance with decrease of the interval l′ among the nano-objects 510.

Accordingly, in view of the density, each of the nano-objects 510 preferably has a volume of 0.52 μm³ or below (which corresponds to a diameter of 1 μm or below if they are spheres in shape). The interval l′ among the nano-objects 510 is preferably 1 μm or below.

The case described next is where the minute structure 50 is a porous membrane 501 provided with circular openings periodically arranged. If the diameter of the openings is a constant value L as shown in FIG. 7(c), the number of the openings per unit area increases and hence the amount of the edges of the openings increases in accordance with decrease of the interval r among the openings 501. On the other hand, as shown in FIG. 7(d), if the metal area separating adjacent two of the openings has a constant width R, the amount of the edges increases in accordance with decrease of the diameter l.

Accordingly, in view of the density, each of the openings preferably occupies an area of 0.8 μm² or below (which corresponds to a diameter of 1 μm or below if they are circles in shape). The diameter is preferably 1 μm or below.

As described above, in view of the electric field strength and of the density, preferred minute structures 50 are as follows. In the case where the minute structure 50 is a porous membrane 501 provided with, particularly, circular openings, each of the openings preferably occupies an area of 80 nm² to 0.8 μm² inclusive, that is, the diameter of each opening is preferably in the range of 10 nm to 1 μm inclusive. More preferably, the diameter of each opening is in the range of 20 nm to 500 nm inclusive, that is, each opening occupies an area of 300 nm² to 0.2 μm² inclusive. Even in the case where the openings are not circles in shape, each opening occupies an area of preferably 80 nm² to 0.8 μm² inclusive, more preferably 300 nm² to 0.2 μm² inclusive.

The diameter of each opening is in the range of preferably 10 nm to 1 μm inclusive, more preferably 20 nm to 500 nm inclusive.

In the case where the minute structure 50 is a group of nano-objects 510 each of which is particularly a sphere in shape, each of the nano-objects 510 preferably has a diameter of 2 nm to 1 μm inclusive on average, namely, preferably has a volume of 4 nm³ to 0.52 μm³ inclusive on average. More preferably, each nano-object 510 has a diameter of 10 nm to 500 nm inclusive on average, namely, has a volume of 520 nm³ to 6.5×10⁻² μm³ inclusive on average.

The average interval among the nano-objects 510 is preferably not less than the above reduced radius calculated according to the formula (1) if each nano-object has a volume of less than 4×10⁻² μm³. However, if the volume is 4×10⁻³ μm³ or more, the average interval is preferably 100 nm or more. However, independently of the volume, the interval is preferably 1 μm or less on average.

<(4) Preferred Thickness of Minute Structure>

Since the electric field-enhancement effect is based on electron localization caused by the skin effect, the minute structure 50 needs to have a thickness d comparable with the skin depth. The skin depth δ, namely, a penetration length in which the initial amplitude of the electromagnetic wave is attenuated to 1/e, is represented by the following formula (2);

$$δ = {[ \frac{ω}{c} \sqrt{\frac{1}{2} ( \sqrt{{ɛ}_{1}^{2} + {ɛ}_{2}^{2}} - {ɛ}_{1} )} ]}^{- 1}$$

In the above formula (2), c is the speed of light in vacuum (3.0×10⁸ [m/s]), ω is the angular frequency of light, ε is the permittivity of the metal, ε₁ is the real part of the permittivity, and ε₂ is the imaginary part of the permittivity (ε=ε₁+iε₂). Since the permittivity depends on the metal, the skin depth also depends on the metal. For example, the skin depth is about 13 nm provided that the permittivity of Al is ε₁=−37 and ε₂=9.5 at the wavelength λ=500 nm (ω=3.8×10¹⁵ [rad/s]). Further, provided that the permittivity of Ag is ε₁=0.6 and ε₂=0.9 at the wavelength λ=318 nm (ω=5.9×10¹⁵ [rad/s]), the skin depth is about 100 nm. In the case of d<<δ, the difference between the electron density on the irradiated side (upper side) and that on the opposite side (lower side) in the minute structure 50 is so small that the generated local electric fields have weak strength. On the other hand, in the case of δ<<d, the electric field of light cannot reach to the lower side and hence cannot oscillate free electrons on the lower side, so that generated local electric fields also have weak strength. Accordingly, if the minute structure 50 has a thickness d ranging from dₘᵢₙ=2 nm to dₘₐₓ=200 nm inclusive, the density difference of free electrons is formed between the irradiated side and the opposite side in the minute structure 50 so as to generate strong local electric fields.

### <(5) Preferred Shape of Metal-Made Minute Structure>

In the case where the minute structure 50 is a porous membrane 501, the openings are not necessarily arranged periodically. Even if they are arrange pseudo-periodically or randomly, the effect of the present invention can be obtained. There are, therefore, no particular restrictions on the arrangement of the openings in the present invention. Further, the shapes of the openings are also not restricted to circles. In view of the electric field-enhancement effect, star-shaped (FIG. 3 (b)) or figure-C-shaped (FIG. 3 (c)) openings are advantageous rather than circular ones (FIG. 3 (a)) because the total peripheral (edge) length of those openings is longer than that of circular openings. On the other hand, however, circular openings have the advantage of easily producing the minute structure 50.

In the case where the minute structure 50 is a group of nano-objects 510, each nano-object 510 may have any shape. For example, it may be a minute sphere 502 (FIG. 3(d)), a minute pillar 503 (FIG. 3(e)) or a minute cone 504 (FIG. 3(f)). Further, even if the nano-objects 510 may be formed at periodical, pseudo-periodical or random positions, the effect of the present invention can be obtained.

<(6) Preferred Position of Minute Structure>

As described above, the minute structure 50 enhances electric fields near the edges therein and this electric field-enhancement effect extends to the photo-active layer 31 so as to improve the photoelectric-conversion efficiency. Accordingly, in order to utilize the local electric fields effectively for carrier generation, the electric field enhancing layer 40 is preferably so constituted that the minute structure 50 is at least partly included in the photoactive layer 31 in the semiconductor layers 30.

<(7) Preferred Material of Metal-Made Minute Structures

In the above, the constitution of a solar cell according to an embodiment of the present invention is described from the structural aspect. However, the materials thereof can be freely selected from known substances.

The minute structure 50 can be made of any known metal, which can be freely selected to use. Here, the “metal” means a material which is an electro-conductive simple substance, which has metallic gloss, which has malleability, which consists of metal atoms and which is solid in room temperature; or an alloy thereof. Since the electric field-enhancement effect is induced by penetration of electromagnetic waves into the minute structure 50, the minute structure 50 in an embodiment is preferably made of materials having metallic gloss. Further, the material of the minute structure 50 preferably less absorbs light in the wavelength range intended to be used.

Examples of the material include Al, Ag, Au, Pt, Ni, Co, Cr, Cu and Ti. For the reasons described above, preferred are Al, Ag, Au, Pt, Ni and Co. The minute structure 50 may be made of an alloy containing at least one selected from the group consisting of Al, Ag, Au, Pt, Ni, Co, Cr, Cu and Ti. However, other metals can be used as long as they have metallic gloss.

### (Semiconductor Material and Junction Structure of Solar Cell)

The semiconductor layer 30 in the solar cell can be made of various known materials, which can be freely selected to use. Examples of the materials include monocrystalline, polycrystalline, fine crystalline and amorphous Si; III-V group and II-VI group compound semiconductors such as GaAs; and chalcopyrite compound semiconductors. The semiconductor layer for photoelectric conversion may be of pn-junction type, of pin-junction type or of tandem type.

### (Method for Production of Solar Cell)

The following describes a method of producing a solar cell according to an embodiment of the present embodiment.

A solar cell produced according the present invention has a photoelectric conversion layer 60, and the photoelectric conversion layer 60 comprises at least a p-type semiconductor layer and an n-type semiconductor layer as the semiconductor layers 30. If amorphous Si is adopted, the solar cell further comprises an i-type semiconductor layer. The solar cell of the present invention is characterized in that the electric field enhancing layer 40 having the metal-made minute structure 50 is provided in those semiconductor layers 30 or at the junction among there.

In the method of producing the solar cell according to the present invention, there are no particular restrictions on the order of procedures for assembling the photoelectric conversion layer 60. Further, the semiconductor layers 30 can be formed by any method according to the kinds of the adopted semiconductors. For example, a p-type or n-type semiconductor substrate may be partly doped with impurities, or otherwise another semiconductor may be deposited on the substrate by, for example, vapor-deposition to form the semiconductor layers 30. The deposition can be carried out by use of known techniques, such as, vapor-deposition, PVD, various CDV methods, sputtering, precipitation coating, spin-coating and dip-coating. Further, the semiconductor layers 30 may be provided by the steps of: forming an electrode layer on a transparent substrate and then depositing thereon a p-type, n-type or i-type semiconductor.

The solar cell according to an embodiment of the present invention is characterized in that the electric field enhancing layer 40 having the metal-made minute structure 50 is positioned in the semiconductor layers 30. This characteristic constitution can be obtained by forming the minute structure in course of the process of forming a p-type, n-type or i-type semiconductor layer 30.

### (Doping Method)

Specifically, the minute structure 50 may be formed in course of formation of a p-type, n-type or i-type semiconductor layer, to produce a substrate provided with the semiconductor layer including the minute structure 50, and subsequently the produced substrate may be doped with impurities.

### (Layering Method)

In another way, the minute structure 50 may be formed in course of the process of overlaying a p-type, n-type or i-type semiconductor layer.

### (Surface, Counter Electrode and Other Improvements for Efficiency)

The light-incident side electrode 10 and the counter electrode 20 may be made of any material as long as it can have an ohmic contact with the contiguous semiconductor layer 30. For example, Ag, Al and Ag/Ti, which are popularly used, are employable. Further, transparent electrodes may be adopted. Meanwhile, there are various attempts for improving the efficiency. For example, the surface of the semiconductor layer 30 on the light-incident side may be coated with an antireflection layer, and/or the top or bottom surface of the photoelectric conversion layer may be improved by use of texture etching or BSF. Those improvements can be applied to the solar cell according to an embodiment of the present invention, unless they impair the effects of the invention.

The following describes examples of the method of forming the minute structure 50, which characterizes the solar cell according to an embodiment of the present invention.

<Method of Producing a Metal-Made Porous Membrane)

In the case where the minute structure 50 is a porous membrane 501, the p-type, n-type or i-type semiconductor layer may be coated with a metal membrane and thereafter the openings may be formed therein. Otherwise, a metal membrane beforehand provided with the openings may be overlaid on the p-type, n-type or i-type semiconductor layer 30.

Further, any method can be adopted to form the fine openings in a metal membrane. For example, in a generally known method, an etching procedure is carried out by use of an electron beam exposure system capable of forming a super-fine structure. According to this method, the fine openings can be readily formed.

Concrete examples of the method will be described below.

### (A. Particle Arrangement Method)

This method comprises the steps of: casting a resist on a metal membrane intended to be the porous membrane 501, to form a resist layer; forming a monolayer of fine particles on the resist layer; forming a dotted resist pattern by use of the monolayer as an etching mask; filling the resist pattern with inorganic substance, to form a reverse pattern mask; and etching the metal membrane through the reverse pattern mask, to form fine openings.

Specifically, if including formation of the semiconductor layers, the above method comprises the sub-steps of: forming a first semiconductor layer; forming a metal membrane having a thickness of 2 nm to 200 nm inclusive on the first semiconductor layer; casting a resist on at least a part of the metal membrane or on at least a part of the first semiconductor layer, to form a resist coating layer; forming a monolayer of fine particles on the resist coating layer; forming a resist pattern of a fine relief pattern by use of the monolayer as an etching mask; forming, on the metal membrane by use of the resist pattern or of a pattern layer obtained from the resist pattern, a pattern having plural openings each of which occupies an area of 80 nm² to 0.8 μm² inclusive on average; and forming a second semiconductor layer on the metal membrane provided with the pattern.

### (B. Block Copolymer Method)

This method comprises the steps of: casting a block copolymer-containing composition on a metal membrane intended to be the porous membrane 501, to form a block copolymer layer; forming dotted microdomains of the block copolymer; etching the dotted microdomains to form a reverse pattern mask; and etching the metal membrane through the reverse pattern mask, to form fine openings.

Specifically, if including formation of the semiconductor layers, the above method comprises the sub-steps of: forming a first semiconductor layer; forming a metal membrane having a thickness of 2 nm to 200 nm inclusive on the first semiconductor layer; forming an intermediate layer on at least a part of the metal membrane or on at least a part of the first semiconductor layer; forming microdomains of a block copolymer on the intermediate layer; forming, on the metal membrane by use of a pattern formed by the microdomains of the block copolymer, a pattern having plural openings each of which occupies an area of 80 nm² to 0.8 μm² inclusive on average; and forming a second semiconductor layer on the metal membrane provided with the pattern.

### (C. Nano-Imprinting Method)

This method comprises the steps of: preparing a stamper whose surface has a fine relief pattern corresponding to the shape of the porous membrane 501 intended to be formed; transferring a resist pattern onto the metal membrane by use of the stamper; and forming a pattern on the metal membrane by use of the resist pattern.

Specifically, if including formation of the semiconductor layers, the above method comprises the sub-steps of: forming a first semiconductor layer; forming a metal membrane having a thickness of 2 nm to 200 nm inclusive on the first semiconductor layer; preparing a stamper whose surface has a fine relief pattern corresponding to the openings intended to be formed; forming a resist pattern by use of the stamper; forming, on the metal membrane by use of the resist pattern, a pattern having plural openings each of which occupies an area of 80 nm² to 0.8 μm² inclusive on average; and forming a second semiconductor layer on the metal membrane provided with the pattern.

### (D. Lift-Off Method)

This method comprises the steps of: directly forming a pattern made of resist or of inorganic substance on a semiconductor layer 30; and then depositing metals or the like among the pattern by, for example, vapor-deposition, to form a porous membrane 501.

### <Method of Producing Nano-Objects>

In the case where the minute structure 50 is a group of nano-objects 510, the p-type, n-type or i-type semiconductor layer 30 may be coated with a metal membrane and thereafter the membrane may be fabricated in spots to form nano-objects 510. Otherwise, metals or the like may be deposited on spots on the p-type, n-type or i-type semiconductor layer 30 to form nano-objects 510.

Further, any method can be adopted to produce the nano-objects 510 from a metal membrane.

Concrete examples of the method will be described below.

### (E. Particle Arrangement Method)

This method comprises the steps of: casting a resist on a metal membrane intended to be the nano-objects 510, to form a resist layer; forming a monolayer of fine particles on the resist layer; forming a resist pattern by use of the monolayer as an etching mask; and etching the metal membrane through the resist pattern, to form nano-objects 510.

Specifically, if including formation of the semiconductor layers, the above method comprises the sub-steps of: forming a first semiconductor layer; forming a metal membrane on the first semiconductor layer; casting a resist on at least a part of the metal membrane or on at least a part of the first semiconductor layer, to form a resist coating layer; forming a monolayer of fine particles on the resist coating layer; forming a resist pattern of a fine relief pattern by use of the monolayer as an etching mask; forming, from the metal membrane by use of the resist pattern or of a pattern layer obtained from the resist pattern, plural nano-objects each of which has a volume of 4 nm³ to 0.52 μm³ inclusive on average and the average distance between adjacent two of which is in the range of 1 nm to 1 μm inclusive; and forming a second semiconductor layer on the nano-objects.

### (F. Block Copolymer Method)

This method comprises the steps of: casting a block copolymer-containing composition on a metal membrane intended to be the nano-objects 510, to form a block copolymer layer; forming dotted microdomains of the block copolymer; etching the metal membrane through the pattern of the dotted microdomains, to form nano-objects 510.

Specifically, if including formation of the semiconductor layers, the above method comprises the sub-steps of: forming a first semiconductor layer; forming a metal membrane on the first semiconductor layer; forming an intermediate layer on at least a part of the metal membrane or on at least a part of the first semiconductor layer; forming microdomains of a block copolymer on the intermediate layer; forming, from the metal membrane by use of a pattern formed according to the microdomains of the block copolymer, plural nano-objects each of which has a volume of 4 nm³ to 0.52 μm³ inclusive on average and the average distance between adjacent two of which is in the range of 1 nm to 1 μm inclusive; and forming a second semiconductor layer on the nano-objects.

### (G. Nano-Imprinting Method)

This method comprises the steps of: preparing a stamper whose surface has a fine relief pattern corresponding to the shape of the nano-objects 510 intended to be formed; transferring, by use of the stamper, a resist pattern onto a metal membrane from which the nano-objects 510 are intended to be formed; and forming a pattern on the metal membrane by use of the resist pattern.

Specifically, if including formation of the semiconductor layers, the above method comprises the sub-steps of: forming a first semiconductor layer; forming a metal membrane on the first semiconductor layer; preparing a stamper whose surface, has a fine relief pattern; forming a resist pattern by use of the stamper; forming, from the metal membrane by use of the resist pattern, plural nano-objects each of which has a volume of 4 nm³ to 0.52 μm³ inclusive on average and the average distance between adjacent two of which is in the range of 1 nm to 1 μm inclusive; and forming a second semiconductor layer on the nano-objects.

### (H. Lift-Off Method)

This method comprises the steps of: directly forming a pattern of openings made of resist or of inorganic substance on a semiconductor layer 30; and then depositing metals or the like in the openings by, for example, vapor-deposition, to form nano-objects 510.

### (I. Solid Phase Deposition Method)

In this method, the nano-objects 510 are deposited on the semiconductor layer 30 as a substrate.

(J. Opening Extension Method)

In this method, openings formed according to the methods (A) to (D) of producing the porous membrane 501 are enlarged so that adjacent openings may be unified to form nano-objects 510.

The present invention is further explained by use of the following examples, but they by no means restrict the present invention.

### Example 1

This example will explain a process of producing a monocrystalline Si solar cell having an electric field enhancing layer 40 provided with nano-objects 510, and properties thereof will be also described below.

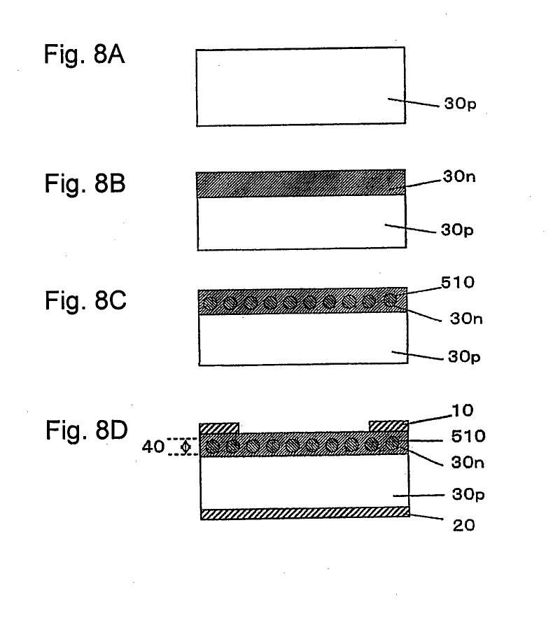

In the present example, a pn-junction was formed by doping in a monocrystalline Si substrate and then Cu-made nano-objects 510 were deposited near the pn-junction. This process will be described below with reference to FIG. 8.

(Formation of pn-Junction in Si Substrate)

First, a p-type Si substrate was prepared as the semiconductor substrate. It was a p-type mono-crystalline Si substrate 30p (B dope: 6×10¹⁵ atom/cm³, thickness: 380 μm) (FIG. 8(a)). On one surface of the p-type monocrystalline Si substrate, an n⁺ layer 30n was formed by the thermal diffusion method to form a pn-junction (FIG. 8(b)). The thermal diffusion was carried out in a POCl₃ gas atmosphere at 1100° C. for 15 minutes. As the semiconductor substrate, poly-crystalline Si may be used. Further, generally known impurities other than B and P may be doped. Furthermore, the doping may be carried out by use of the ion implantation technique.

### (Deposition of Cu on Si Substrate)

Subsequently, nano-objects 510 were formed near the pn-junction in the Si substrate 30 (FIG. 3(c)) in the following manner. The Si substrate was exposed to Cu-ion beams (acceleration energy: 60 keV), so as to implant Cu ions. The projected range was estimated to be about 50 nm, and the dose rate and the integral dose were 45 μA/cm² and 3×10¹⁶ ions/cm², respectively. The section of the resultant substrate was observed by TEM. As a result, it was found that there was a fine particle-depletion layer of about 10 nm thickness immediately under the surface. Further, it was also verified that there were Cu-made fine particles of 10 to 15 nm diameter distributed two-dimensionally under the depletion layer.

After annealed at 800° C., the substrate was analyzed by SIMS. As a result, the peak concentration of impurities was found to be about 5×10²⁰ atom/cm³ and the depletion layer was estimated to be formed at the depth of about 100 nm from the surface. Further, the annealing procedure extended distribution of the particles in the thickness direction, so that the fine particles were dispersed in the semiconductor layer 30 within the depth range of 120 nm. The part where the fine particles 510 were dispersed in the semiconductor layer 30 serves as the electric field enhancing layer 40.

The particle size and the particle distribution in the depth direction can be controlled by the dose rate and by the thermal anneal treatment after the ion implantation, respectively, and hence they can be freely selected.

### (Constitution of Electric Field Enhancing Layer)

The above procedures gave an electric field enhancing layer in which plural Cu-made nano-objects were randomly arranged between the p- and n-layers of monocrystalline Si. Each of the nano-objects had a diameter of 12 nm on average (a volume of 900 nm³ on average), and the distance among them was 10 nm on average.

### (Production of Solar Cell)

For producing a solar cell, a light-incident side electrode 10 and a counter electrode 20 were provided on the n⁺-type Si layer 30n and on the p-type Si layer 30p, respectively. The electrodes were formed from epoxy-type thermosetting Ag paste according to the screen printing method. The counter electrode 20 was formed all over the surface in a thickness of about 40 μm, and the light-incident side electrode 10 was formed in a thickness of about 40 μm and in plural lines of about 200 μm width and about 2 mm pitch (FIG. 8(d)).

### (Properties of Solar Cell)

The solar cell thus produced in Example 1 was exposed to pseudo-sunlight of AM 1.5, to evaluate the photoelectric conversion efficiency at room temperature. As a result, it showed as good a photoelectric conversion efficiency as 10.1%. This result indicated the effect of the electric field enhancing layer 40. Further, the same procedures were repeated except for changing the material of the nano-objects 510 from Cu into other metal, and as a result it was found that the conversion efficiency was 10.5% or 10.6% when the metal material was Au or Ag, respectively. Those results showed the effect of the present invention.

### Reference Example 1

The procedures of Example 1 were repeated to form a pn-junction of monocrystalline Si, but thereafter the metal fine particles (nano-objects 510) were not formed to produce a solar cell, whose photoelectric conversion efficiency was found to be 8.9%.

### Example 2-1

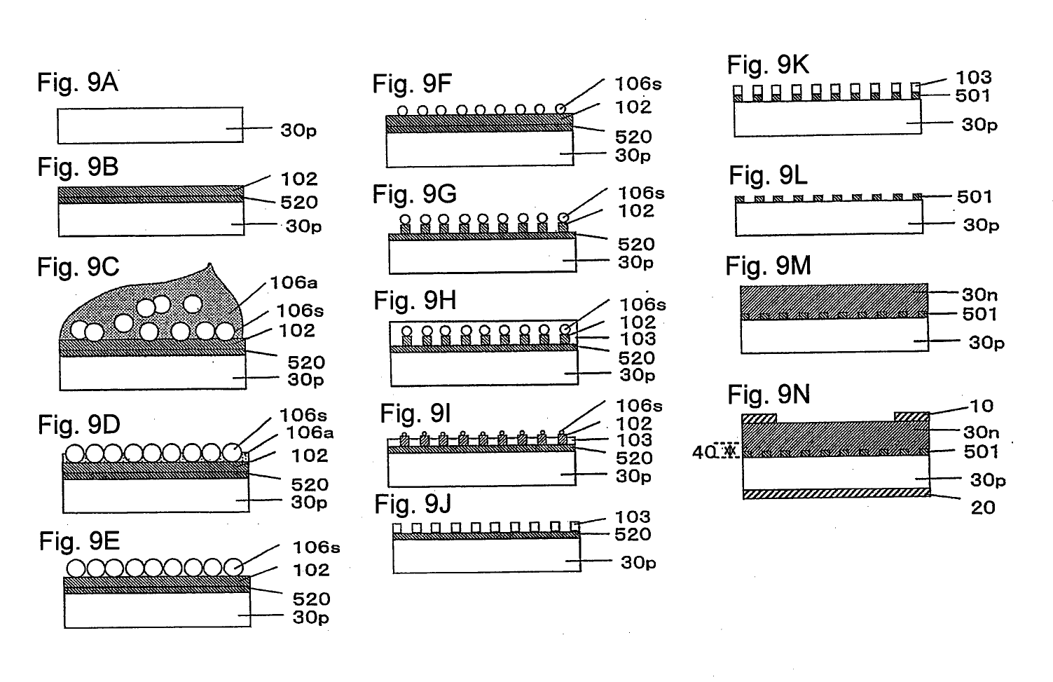

This example will explain a method of producing a polycrystalline Si solar cell having an electric field enhancing layer 40 provided with a porous membrane 501, and properties thereof will be also described below. In the present example, an Al membrane on a poly-crystalline Si substrate was etched and then poly-crystalline Si was deposited thereon by CVD to form an Al-made porous membrane 501 in semiconductor layers 30. This process will be described below with reference to FIG. 9.

### (P-Type Si: Substrate)

First, a B-doped p-type polycrystalline Si substrate 30p (B dope: 10¹⁵ atom/cm³, thickness: 300 μm) was prepared (FIG. 9(a)). In this embodiment, generally known impurities other than B may be doped and it is also possible to prepare an n-type substrate, on which a p-layer may be thereafter formed.

### (Al-Made Porous Membrane on Si Substrate)

Next, a minute structure 50, which was an Al-made porous membrane in this example, was formed on the Si substrate in the following manner. On the major face of the p-type Si substrate 30p, Al was vapor-deposited in vacuum to form a membrane 520 of 30 nm thickness.

The Al membrane 520 deposited on the substrate was spin-coated with an i-ray thermosetting resist, and then annealed in a nitrogen atmosphere at 250° C. for 1 hour to make the thermosetting reaction proceed and thereby to form a resist layer 102 of about 240 nm thickness (FIG. 9(b)).

Independently, a dispersion solution containing fine silica particles 106s of 200 nm diameter (PL-13 [trademark], manufactured by Fuso Chemical Co,, Ltd.) was diluted to 5 wt. % with a composition 106a containing acrylic monomers, and then filtered to remove secondary particles. The obtained dispersion solution of fine silica particles was spin-coated at 2000 rpm for 60 seconds on the above resist layer 102 formed on the substrate (FIG. 9(c)), and annealed in a nitrogen atmosphere at 150° C. for 1 hour.

Thereafter, the substrate was cooled to room temperature, and thereby a regularly arranged mono-particle layer of fine silica particles 106s was formed on the above hydrophilized resist layer 102 (FIG. 9(d)). In the present example, fine silica particles were adopted as the fine particles 106s. However, fine particles of any organic or inorganic material can be used as long as they can realize the below-described unevenness of etching rate. The size of the fine particles 106s is determined according to the pitch of openings on the porous membrane 501 intended to be produced, but generally is 60 to 700 nm.

The monoparticle layer of fine silica particles 106s was etched by means of a reactive ion etching (RIE) apparatus (manufactured by SAMCQ Inc.) for 20 seconds under the conditions of O₂: 30 sccm, 10 mTorr and a RF power of 100 W, to remove excess of the composition 106a containing acrylic monomers (FIG. 9(e)). Successively, the monoparticle layer was etched for 2 minutes under the conditions of CF₄: 30 sccm, 10 mTorr and a RF power of 100 W, to slim the silica particles. The results were observed by electron microscopy, and thereby it was found that the silica particles 106s had diameters of about 120 nm and that the interval among them was about 80 nm (FIG. 9(f)).

Subsequently, the underlying thermosetting resist layer was etched for 270 seconds by use of the remaining fine silica particles 106s as a mask under the conditions of O₂: 30 sccm, 2 mTorr and a RF power of 100 W. As a result, pillar structures of high aspect ratios were formed in the area where the silica particles 106s had been positioned in the early steps, to obtain a pattern of pillars (FIG. 9(g)).

The obtained pillar resist pattern 102 was then spin-coated with a spin-on-glass (hereinafter, referred to as SOG) solution (SOG-14000 [trademark], manufactured by Tokyo Ohka Kogyou Co., Ltd.), and annealed in a nitrogen atmosphere at 250° C. for 1 hour. In this way, the gaps among the pillars of the resist pattern 102 were filled with SOG (FIG. 9(h)).

Thereafter, the SOG layer 103 formed in the previous step and the slimed fine silica particles 106s buried therein were etched for 11 minutes under the conditions of CF₄: 30 sccm, 10 mTorr and a RF power of 100 W, so that the SOG 103 and silica particles 106s lying on the pillar resist pattern 102 were removed to form a composite of the pillar resist pattern 102 and the SOG filling the gaps among the pillars (FIG. 9(i)).

The thermosetting resist 102 in pillar shapes was then etched for 150 seconds under the conditions of O₂: 30 sccm, 10 mTorr and a RF power of 100 W, to form a SOG mask 103 (second etching mask) on the Al membrane 520. The SOG mask 103 had a pattern in reverse to the above pillar resist pattern (FIG. 9(j)).

Successively, the Al membrane 520 was etched through the obtained SOG mask 103 by means of an ICP-RIE apparatus (manufactured by SAMCO Inc.) in the following manner. First, the Al membrane 520 was subjected to sputter etching for 1 minute under the conditions of Ar: 25 sccm, 5 mTorr, an ICP power of 50 W and a Bias power of 150 W, to remove a naturally oxidized thin layer of Al₂O₃ formed on the surface. Thereafter, the Al membrane 520 was further etched for 50 seconds by use of a Cl₂Ar mixed gas (Cl₂/Ar:2.5/25 sccm) under the conditions of 5 mTorr, an ICP power of 50 W and a Bias power of 150 W (FIG. 9(k)).

Furthermore, the etching procedure was carried out for 150 seconds under the conditions of CF₄: 30 sccm, 10 mTorr and a RF power of 100 W, to remove the remaining SOG mask 103.

### (Constitution of Electric Field Enhancing Layer)

The above procedures gave an Al-made porous membrane 501 on the p-layer 30p (FIG. 9(l)). The formed porous membrane had a thickness of 30 nm and openings each of which occupied an area of 9.9×10³ nm² (which corresponded to a diameter of 112 nm) on average. The average opening ratio was 28.4%.

### (Re-Growth of Polycrystalline Si on Al-Made Porous Membrane)

On the Al-made porous membrane 501, an n⁺-type polycrystalline Si layer 30n of 50 nm thickness was formed according to the plasma CVD method under the conditions that the temperature of the substrate was 400° C. and the materials gases were SiH₄, H₂ and PH₃. In this procedure, the openings of the Al-made porous membrane 501 were filled with the n⁺-type polycrystalline Si 30n (FIG. 9(m)).

### (Production of Solar Cell)

For producing a solar cell, a light-incident side electrode 10 and a counter electrode 20 were provided on the n⁺-type Si layer 30n and on the p-type Si layer 30p, respectively, according to the screen printing method (FIG. 9(n)). The specifications and conditions of forming the electrodes were the same as those in Example 1.

### (Properties of Solar Cell)

The solar cell produced above in Example 2-1 was evaluated in the same manner as in Example 1. As a result, it showed as good a photoelectric conversion efficiency as 6.5%. This result indicated the effect of the electric field enhancing layer 40. In the present example, the p-layer 30p was provided before the n-layer 30n. However, even if the n-layer 30n is adopted as the substrate and thereafter the minute structure 50 and the p-layer 30p are formed in this order, the same result can be obtained. The same procedures were repeated except for changing the material of the porous membrane 501 from Al to other metal, and as a result it was found that the conversion efficiency was 6.7%, 6.8% or 6.1% when the metal material was Au, Ag or Cu, respectively. Those results showed the effect of the present invention. The porous membrane 501 can be formed according to any of the methods described above, and there are no particular restrictions.

### Example 2-2

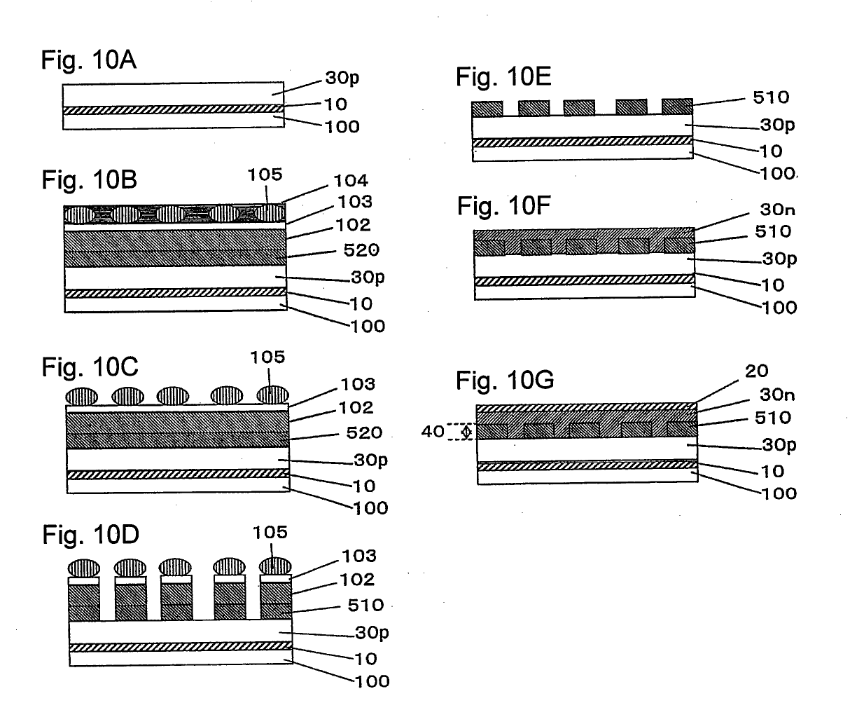

This example will explain a process in which the metal-made porous membrane 501 in Example 2-1 is replaced with a group of Au-made nano-objects 510. The process will be described with reference to FIG. 10.

### (P-Type Si Substrate)

As the semiconductor substrate, the p-type polycrystalline Si substrate 30p same as in Example 2-1 was prepared.

### (Au Fine Particles)

In the present example, Au-made nano-objects 501 were formed by the method utilizing phase separation of block co-polymer in the following manner.

First, on a transparent substrate 100, a light-transmission type electrode 10 as the light-incident side electrode and a p-type polycrystalline Si layer 30p were formed to produce a substrate of the cell (FIG. 10(a)). On the produced substrate, Au was vapor-deposited in vacuum to form an Au membrane 520 of 30 nm thickness. The Au membrane was then spin-coated with a resist, and annealed at 250° C. for 1 hour to form a resist layer 102 of about 100 nm thickness. The resist layer 102 was further spin-coated with a SOG solution, and annealed at 250° C. for 1 hour to form a SOG layer 103 of about 30 nm thickness. This procedure gave an intermediate layer consisting of the resist and SOG.

Independently, a block co-polymer of polystyrene (PS)-polymethyl methacrylate (PMMA) and PMMA (Mw: 1500) were mixed in a weight ratio of 6:4, and the mixture was dissolved in propylene glycol monomethyl ether acetate (PGMEA) in an amount of 3 wt. %. The solution was then spin-coated on the above substrate at 2000 rpm for 30 seconds, and pre-baked at 110° C. for 90 seconds to evaporate the solvent and thereby to form a layer of 120 nm thickness.

Successively, the layer was annealed in a nitrogen atmosphere at 210° C. for 4 hours to induce phase separation between PS and PMMA and thereby to form a block co-polymer layer 104. The block co-polymer had molecular weights of 78000 g/mol at the PS domains and 17000 g/mol at the PMMA domains, and showed morphology in which dotted PS micro-domains 105 of about 50 to 90 nm diameter were dispersed in PMMA matrix (FIG. 10(b)).

The block co-polymer layer 104 was then etched under the conditions of O₂: 30 sccm, 10 mTorr and a RF power of 100 W, so as to remove the PMMA matrix selectively in the block co-polymer layer 104 and thereby to completely bare the SOG layer 103 in the areas immediately under the PMMA domains (FIG. 10(c)). Successively, the SOG layer 103 was etched by CF₄-RIR through the remaining PS 105 as a mask. As a result of the etching, the dot pattern of PS 105 was transferred onto the SOG layer 103 and thereby a pattern of the SOG layer 103 was formed according to the phase separation of the block co-polymer. Thereafter, the underlying thermosetting resist layer was etched by O₂-RIE through the pattern of the SOG layer 103 as a mask. As a result, pillar structures of high aspect ratios were formed in the areas where the PS dots 105 were positioned, to obtain a pattern of pillars (FIG. 10(d)).

The Au membrane 520 was then etched for 45 seconds through the obtained pattern as a mask by means of an ion beam milling apparatus under the conditions of Ar gas: 5 sccm, ion source power; 500 V and 40 mA.

The above procedures gave a group of arranged Au-made nano-objects 510 having a thickness of 30 nm. Each of the nano-objects had a volume of 5.9×10⁴ nm³ on average, and the center-to-center distance between adjacent two of them was 76 nm on average. The electric field enhancing layer contained Au in a volume ratio of 39%. Thereafter, the mask on the arranged Au-made nano-objects 510 was removed by ultrasonic washing (FIG. 10(e)).

Subsequently, an n⁺-layer was formed thereon according to the plasma CVD method in the same manner as in Example 2-1 (FIG. 10(f)). Further, electrodes were provided in the same manner as in Example 2-1, to produce a solar cell (FIG. 10(g)).

The solar cell thus produced was evaluated in the same manner as in Example 1. As a result, it showed as good a photoelectric conversion efficiency as 6.4%. Further, the same procedures were repeated except for changing the material of the metal membrane 520 from Au into other metal, and as a result if was found that the conversion efficiency was 6.4%, 6.5% or 6.1% when the metal material was Al, Ag or Cu, respectively. Those results showed the effect of the present invention.

### Reference Example 2

The procedures of Examples 2-1 and 2-2 were repeated to produce a p-type polycrystalline Si substrate 30p provided with a light-incident side electrode 10, but thereafter an n⁺-layer 30n and a counter electrode 20 were successively formed in this order without forming the minute substrate 50 to produce a solar cell, whose photoelectric conversion efficiency was found to be 5.0%.

### Example 3-1

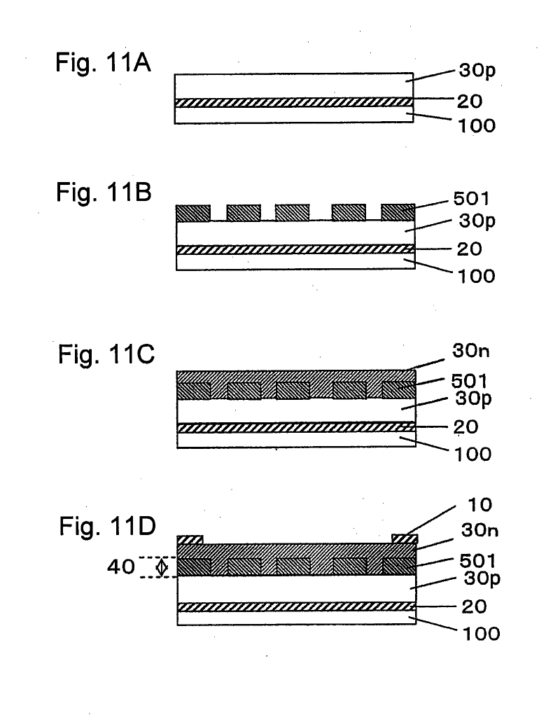

This example will explain a process in which a p-type polycrystalline Si membrane is adopted as the Si substrate. The process will be described with reference to FIG. 11. On a SiO₂ surface of a substrate 100, a counter electrode 20 was formed and then a p-type polycrystalline Si membrane was formed thereon according to the plasma CVD method by use of dichlorosilane, H₂ and N₂ under the condition that the substrate temperature was 400° C. The formed polycrystalline Si membrane 30p had a thickness of 1 μm (FIG. 11(a)). Subsequently, an Al-made porous membrane 501 (FIG. 11(b)) and an n⁺-layer 30n (FIG. 11(c)) were successively formed in this order in the same manner as in Example 2-1. Further, a light-incident side electrode 10 was provided thereon to produce a solar cell (FIG. 11(d)). The solar cell thus produced was evaluated in the same manner as in Example 1. As a result, it showed as good a photo-electric conversion efficiency as 4.9%. Further, the same procedures were repeated except for changing the material of the metal membrane 520 from Al into other metal, and as a result it was found that the conversion efficiency was 5.0%, 5.0% or 4.7% when the metal material was Au, Ag or Cu, respectively. Those results showed the effect of the present invention.

This example indicates that electric filed enhancement of the porous membrane 501 enables even a thin semiconductor layer to absorb light enough to realize high conversion efficiency.

### Example 3-2

The polycrystalline Si thin film solar cell of Example 3-1 was so modified in this example that the Al-made porous membrane 501 was replaced with a group of Au-made nano-objects 510. The Au-made nano-objects 510 were formed between the p-layer 30p and the n⁺-layer 30n in the same manner as in Example 2-2. The solar cell thus produced was evaluated in the same manner as in Example 1. As a result, it showed as good a photoelectric conversion efficiency as 4.9%. Further, the same procedures were repeated except for changing the material of the metal membrane 520 from Au into other metal, and as a result it was found that the conversion efficiency was 4.8%, 4.9% or 4.6% when the metal material was Al, Ag or Cu, respectively. Those results showed the effect of the present invention.

This example also indicates that electric filed enhancement of the minute structure 50 enables even a thin semiconductor layer to absorb light enough to realize high conversion efficiency.

### Reference Example 3

The procedures of Examples 3-1 and 3-2 were repeated to produce a counter electrode 20 on a SiO₂ substrate and a p-type polycrystalline Si thin film substrate 30p thereon, but thereafter an n⁺-layer 30n and a light-incident side electrode 10 were successively formed in this order without forming the minute substrate 50 to produce a solar cell, whose photo-electric conversion efficiency was found to be 4.2%.

### Example 4-1

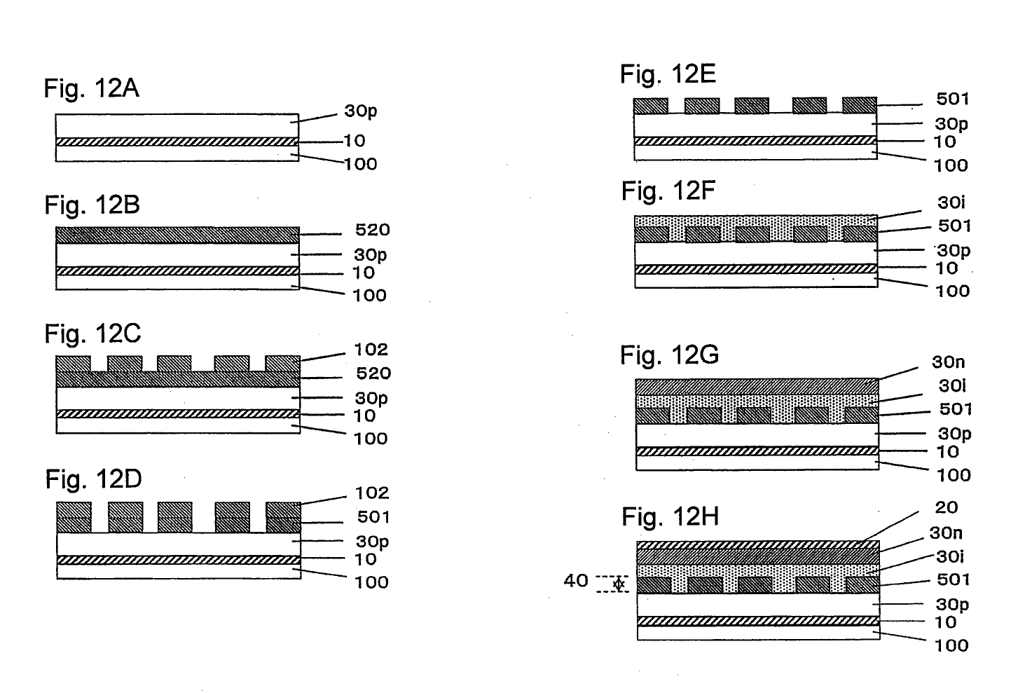

This example will explain a process in which an Au-made porous membrane 501 is formed between a p-layer 30p and an i-layer in a pin structure of amorphous Si. In the present example, an Au membrane on a p-type substrate 30p was etched to form a Au-made porous membrane 501 and then an i-layer 30i and an n-layer 30n were successively overlaid thereon, to form a minute structure 50 in semiconductor layers. This process will be described with reference to FIG. 12.

### (P-Type Si Substrate)

First, on a transparent glass substrate 100, a layer mainly comprising tin oxide (SnO₂) as the light-incident side electrode 10 was formed at about 500° C. in a thickness of about 500 nm to 800 nm by means of a thermal CVD apparatus. The light-incident side electrode 10 thus formed had a surface of moderately rough texture. Subsequently, on the light-incident side electrode 10, a p-layer 30p of 20 nm thickness was formed from SiH₄ and H₂ gases as the main materials and B₂H₆ as the doping gas by means of the plasma CVD apparatus (FIG. 12(a)).

(Au-Made Porous Membrane on p-Type Si Substrate)

Subsequently, Au was vapor-deposited in vacuum thereon to form a metal membrane 520 of Au having a thickness of 30 nm (FIG. 12(b)). The metal membrane 520 was spin-coated with an i-ray thermosetting resist, to form a resist layer 102 of about 150 nm thickness. Onto the resist layer 102, a fine relief pattern corresponding to the designed openings was transferred by use of a stamper as the mold in the following manner. In this example, a quartz plate was fabricated by means of electron beam-lithography to prepare the stamper. On the surface of the stamper, holes of 120 nm depth and of about 300 nm diameter were aligned in the closest packing arrangement with a period of 500 nm. In the process of producing the solar cell, there are no particular restrictions on the material of the stamper and on the method of forming the fine relief pattern on the stamper. For example, it is possible to form the stamper by use of fine particles or of block copolymer in the manners described above. The surface of the stamper was then coated with a fluorine-containing releasing agent such as perfluoropolyether, to lower the surface energy of the stamper enough to improve the releasability. Successively, the stamper was pressed onto the resist layer 102 by use of a heater plate press under the conditions that the substrate temperature was 125° C. and the stamping pressure was 6.7 kN/cm², and then cooled for 1 hour to room temperature. When the stamper was released vertically, it was found that the pattern of the stamper was reversely transferred onto the resist layer 102. In this way, a periodical opening resist pattern 102 was formed (FIG. 12(c)), The resist pattern 102 was constituted of periodically arranged pillars of 320 nm diameter. The embodiment of this example is not restricted to the thermal nano-imprinting process described above, and the functions of the resultant solar cell are not impaired even if the same pattern is formed by use of other imprinting techniques such as photo-imprinting and soft imprinting.

The Au membrane 520 described above was then etched for 45 seconds through the obtained resist pattern as a mask by means of an ion beam milling apparatus under the conditions of Ar gas: 5 sccm, ion source power: 500 V and 40 mA (FIG. 12(d)). Thereafter, the resist layer 102 lying on the Au membrane 520 was removed by O₂-RIE.

The above procedures gave an Au-made porous membrane (FIG. 12(e)) having a thickness of 30 nm and also having openings each of which occupied an area of 8.0×10⁻² μm² (corresponding to a diameter of 320 nm) on average. The average opening ratio was 37.1%.

(i-Layer and n-Layer on Au-Made Porous Membrane)

The substrate was again placed in the vacuum chamber, and amorphous Si i- and n-layers 30i and 30n were formed on the Au-made porous membrane in the following manners. Similarly to the p-layer 30p, an i-layer 30i of i-type Si was formed from SiH₄ gas in a thickness of 300 nm (FIG. 12(f)) and then successively an n-layer 30n was formed thereon from a mixed gas of PH₃ and SiH₄ in a thickness of 30 nm (FIG. 12(g)) by means of the plasma CVD apparatus. In this procedure, the openings of the Au-made porous membrane 501 were filled with the i-type amorphous Si 30i. Thereafter, a counter electrode 20 was provided on the surface of the n-layer 30 (FIG. 12(h)).

### (Production and Properties of Solar Cell)

The solar cell thus produced was evaluated in the same manner as in Example 1. As a result, it showed as good a photoelectric conversion efficiency as 4.8%. Further, the same procedures were repeated except for changing the material of the metal membrane 520 from Au to other metal, and as a result it was found that the conversion efficiency was 4.7%, 4.9% or 4.7% when the metal material was Al, Ag or Cu, respectively. Those results showed the effect of the present invention.

In order to improve interface properties, a buffer layer may be provided between the p-layer 30p and the i-layer 30i.

(Additional Au-Made Porous Membrane Between i-Layer and n-Layer)

Another solar cell was produced in which the Au-made porous membrane 501 was also provided between the i-layer and the n-layer as well as that between the p-layer and the i-layer. As a result, it showed as good a photoelectric conversion efficiency as 4.9%. Further, the same procedures were repeated except for changing the material of the metal membrane 520 from Au into other metal, and as a result it was found that the conversion efficiency was 4.8%, 4.9% or 4.7% when the metal material was Al, Ag or Cu, respectively. Those results showed the effect of the present invention.

### Example 4-2

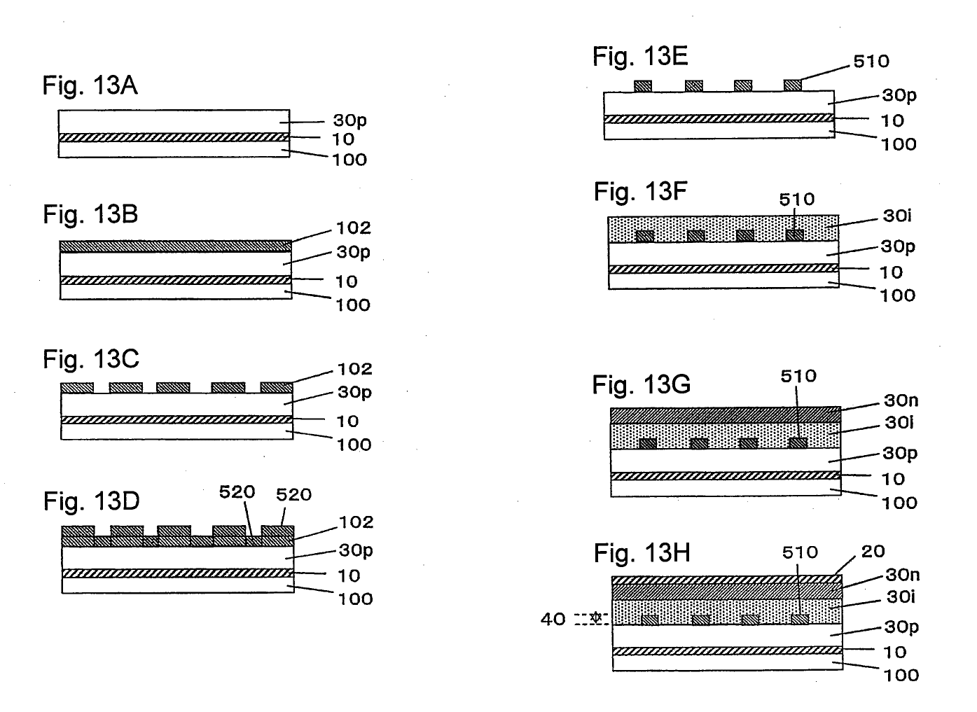

The amorphous Si solar cell of Example 4-1 was so modified in this example that the Au-made porous membrane was replaced with a group of Ag-made nano-objects 510. This process will be described with reference to FIG. 13.

First, in the same manner as in Example 4-1, a light-incident side electrode 10 and a p-type amorphous Si layer 30p were successively formed on a transparent glass substrate 100 (FIG. 13(a)).

Subsequently, a group of Ag-made nano-objects 510 were formed on the surface of the p-type amorphous Si layer 30p by the process described below. First, the p-type amorphous Si layer 30p was spin-coated to form a thin resist layer 102 (FIG. 13(b)).

Onto the formed resist layer 102, a fine relief pattern corresponding to the nano-objects intended to be formed was transferred by use of a stamper as the mold in the following manner. In this example, a quartz plate was fabricated by means of electron beam-lithography to prepare the stamper. On the surface of the stamper, pillars of 120 nm height and of about 320 nm diameter were aligned in the closest packing arrangement with a period of 500 nm. The stamper thus prepared was employed to form a porous resist mask 102 in the same manner as in Example 4-1 (FIG. 13(c)). Thereafter, Ag was vapor-deposited in vacuum on the porous resist mask 102 in a thickness of 30 nm (FIG. 13(d)), and then the resist was removed by ultrasonic washing to form a Ag-made dot pattern 510 on the p-type amorphous Si layer 30p (FIG. 13(e)).

The p-type amorphous Si layer 30p thus provided with Ag fine particles 510 thereon was used as the substrate, on which an i-layer 30i (FIG. 13(f)) and an n-layer 30n (FIG. 13(g)) were successively formed. Further, a counter electrode 20 was provided in the same manner as in Example 4-1, to produce a solar cell (FIG. 13(h)).

The solar cell thus produced was evaluated in the same manner as in Example 1. As a result, it showed as good a photoelectric conversion efficiency as 4.7%. Further, the same procedures were repeated except for changing the material of the nano-objects 510 from Ag to other metal, and as a result it was found that, the conversion efficiency was 4.6%, 4.6% or 4.5% when the metal material was Al, Au or Cu, respectively. Those results showed the effect of the present invention.

Another solar cell was produced in which the Ag-made nano-objects were also provided between the i-layer and the n-layer as well as those between the p-layer and the i-layer. As a result, it showed as good a photoelectric conversion efficiency as 4.9%. Further, the same procedures were repeated except for changing the material of the metal membrane 520 from Ag into other metal, and as a result it was found that the conversion efficiency was 4.8%, 4.8% or 4.6% when the metal material was Al, Au or Cu, respectively. Those results showed the effect of the present invention.

### Reference Example 4

The procedures of Examples 4-1 and 4-2 were repeated to produce an amorphous Si solar cell not comprising the metal-made minute structure 50. The photoelectric conversion efficiency of the solar cell was found to be 4.5%.

### Example 5-1

This example will explain a process in which a pin-junction of fine crystalline Si is formed according to the plasma CVD method and then an Ag-made porous membrane 510 is formed between the p-layer 30p and the i-layer 30i.

### (Deposition of Fine Crystalline Si for Forming (p, i, n) Layers)

First, in the same manner as in Example 4-1, a light-incident side electrode 10 and a p-type fine crystalline Si layer 30p were successively provided on a transparent glass substrate 100. The fine crystalline Si layer 30p was formed according to the plasma CVD method at a substrate temperature of 200° C. or below from SiH₄ diluted with H₂ as the material gas and B₂H₆ diluted with H₂ as the doping gas.

Subsequently, an Ag-made porous membrane 501 was formed on the fine crystalline Si layer 30p in the same manner as in Example 4-1.

On the formed Ag-made porous membrane 501, an i-layer 30i and an n-layer 30n were formed according to the plasma CVD method. In this procedure, the openings of the Ag-made porous membrane 501 were filled with the i-type fine crystalline Si 30i. Thereafter, a counter electrode 20 was provided on the surface of the n-layer 30n, to produce a solar cell.

The solar cell thus produced was evaluated in the same manner as in Example 1. As a result, it showed as good a photoelectric conversion efficiency as 4.8%. Further, the same procedures were repeated except for changing the material of the metal membrane 520 from Ag into other metal, and as a result it was found that the conversion efficiency was 4.5%, 4.6% or 4.4% when the metal material was Al, Au or Cu, respectively. Those results showed the effect of the present invention.

### Example 5-2

This example will explain a process in which a pin-junction of fine crystalline Si is formed according to the plasma CVD method and then Au-made nano-objects 501 are formed between the p-layer 30p and the i-layer 30i.

After a substrate 100, a light-incident side electrode 10 and a p-layer 30p of fine crystalline Si were prepared in the same manner as in Example 5-1, Au-made nano-objects 510 were formed on the p-layer 30p according to the nano-imprinting process described in Example 4-1. However, the stamper used in this example had a pattern in reverse to the pattern of that used in Example 4-1. As a result, the obtained layer had a pattern in which columnar Au-made nano-objects 510 were aligned in a triangular lattice arrangement. Each of the nano-objects 510 had a height of 30 nm, a diameter of 320 nm and a volume of 2.4×10⁻³ μm³ on average, and the center-to-center distance between adjacent two of them is 500 nm on average.

Subsequently, an i-layer 30i and an n-layer 30n were formed thereon according to the plasma CVD method in the same manner as in Example 5-1. Thereafter, a counter electrode 20 was provided to produce a solar cell.

The solar cell thus produced was evaluated in the same manner as in Example 1. As a result, it showed as good a photoelectric conversion efficiency as 4.5%. Further, the same procedures were repeated except for changing the material of the metal membrane 520 from Au into other metal, and as a result it was found that the conversion efficiency was 4.5%, 4.5% or 4.4% when the metal material was Al, Ag or Cu, respectively. Those results showed the effect of the present invention.

### Reference Example 5

The procedures of Examples 5-1 and 5-2 were repeated to produce a fine crystaline Si solar cell not comprising the metal-made minute structure 50. The photoelectric conversion efficiency of the solar cell was found to be 4.1%.

### Example 6-1

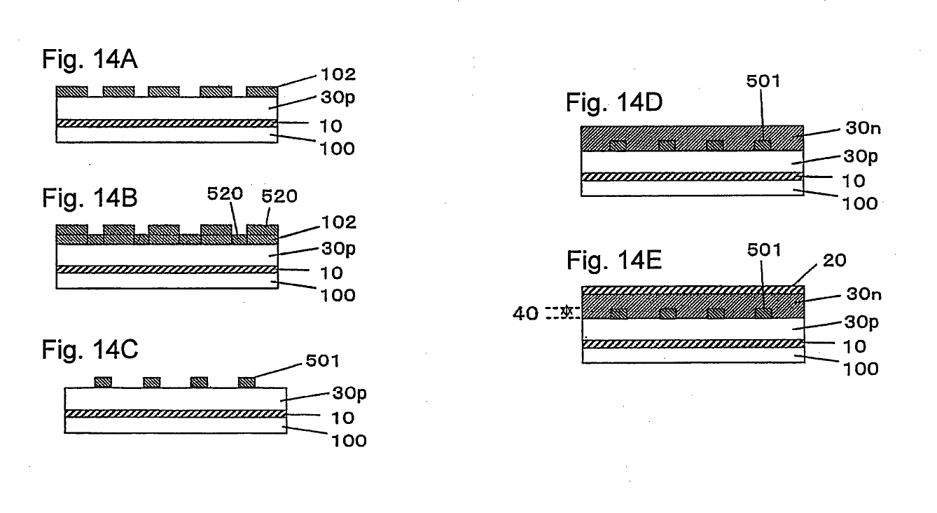

This example will explain a process of producing a GaAs compound semiconductor solar cell having an electric field enhancing layer 40 provided with a porous membrane 501, and properties thereof will be also described below with reference to FIG. 14. The porous membrane 501 was made of Al in the present example.

First, an Al-made porous membrane 501 was formed on a p-type GaAs wafer 30p by the following procedures.

In the same manner as in Example 2-2, a resist pattern 102 consisting of pillars having high aspect ratios was formed on a p-type GaAs wafer 30p (FIG. 14(a)). Successively, Al was vapor-deposited on the formed pillar pattern 102 in a thickness of 30 nm (FIG. 14(b)). After that, the pillar pattern 102 was removed by lift-off treatment in which it was subjected to ashing treatment by use of O₂ plasma and then to ultrasonic washing in water. Thus, a porous membrane 501 provided with desired openings was formed on the p-type GaAs substrate 30p (FIG. 14(c)).

The Al-made porous membrane 501 thus formed had a thickness of 30 nm and openings each of which occupied an area of 2.0×10³ nm² (corresponding to a diameter of 50 nm) on average. The center-to-center distance between adjacent two of the openings was 70 nm on average, and the average opening ratio was 52%.

The p-type GaAs wafer 30p thus provided with the Al-made porous membrane 501 thereon was used as the substrate, on which n⁺-type GaAs 30n was deposited according to MOCVD (FIG. 14(d)). In this procedure, the openings of the Al-made porous membrane 501 were filled with the n⁺-type GaAs.

As the materials, Au/Au—Zn (3%) and Au—Ge (0.5%) were used for the electrode (light-incident side electrode 10) on the p-type GaAs 30p surface and that (counter electrode 20) on the n⁺-type GaAs 30n surface, respectively. Those electrodes (light-incident side electrode 10 and counter electrode 20) were so formed by vapor-deposition that they had the same shapes as those in Example 1 (FIG. 14(e)).

The GaAs solar cell thus produced was evaluated in the same manner as in Example 1. As a result, it showed as good a photoelectric conversion efficiency as 6.2%. Further, the same procedures were repeated except for changing the material of the metal membrane 520 from Al into other metal, and as a result it was found that the conversion efficiency was 6.5%, 6.6% or 6.4% when the metal material was Au, Ag or Cu, respectively. Those results showed the effect of the present invention.

### Example 6-2

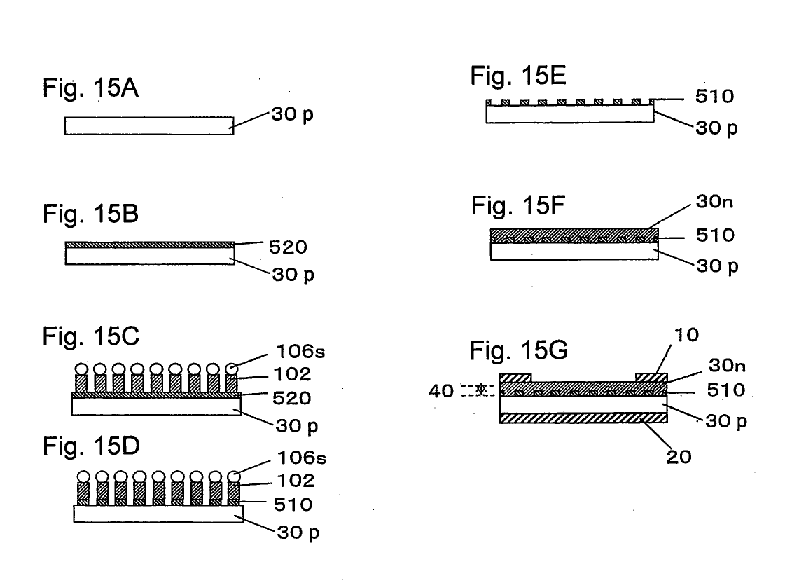

This example will explain a process of producing a GaAs compound semiconductor solar cell having an electric field enhancing layer 40 provided with nano-objects 510, and properties thereof will be also described below with reference to FIG. 15. The nano-objects 510 were made of Al in the present example.

First, Al-made nano-objects 510 were formed on a p-type GaAs wafer 30p.

The procedures of forming the nano-objects 510 were as follows.

On a p-type GaAs substrate 30p (FIG. 15(a)), Al was vapor-deposited in vacuum to form a membrane 520 of 30 nm thickness (FIG. 15(b)). Successively, resist pillars 102 of high aspect ratios were formed on the Al membrane 520 by use of silica particles in the same manner as in Example 2-1 (FIG. 15(c)). The Al membrane 520 was then etched through the resist pattern 102 as a mask by means of an ICP-RIE apparatus (FIG. 15(d)). The conditions for etching were the same as those in Example 2-1. After that, the remaining resist mask 102 was removed by O₂ etching with a reactive etching apparatus to form Al-made nano-objects 510 (FIG. 15(e)). Each of the formed nano-objects 510 had a diameter of 112 nm on average, and the center-to-center distance among them was 200 nm on average.

The p-type GaAs wafer 30p thus provided with the Al-made nano-objects 510 thereon was used as the substrate, on which n⁺-type GaAs 30n was deposited according to MOCVD (FIG. 15(f)).

As the materials, Au/Au—Zn (3%) and Au—Ge (0.5%) were used for the electrode (light-incident side electrode 10) on the p-type GaAs 30p surface and that (counter electrode 20) on the n⁺-type GaAs 30n surface, respectively. Those electrodes were so formed by vapor-deposition that they had the same shapes as those in Example 1 (FIG. 15(g)).

The GaAs solar cell thus produced was evaluated in the same manner as in Example 1. As a result, it showed as good a photoelectric conversion efficiency as 6.4%. Further, the same procedures were repeated except for changing the material of the metal membrane 520 from Al into other metal, and as a result it was found that the conversion efficiency was 6.5%, 6.6% or 6.3% when the metal material was Au, Ag or Cu, respectively. Those results showed the effect of the present invention.

### Reference Example 6

The procedures of Examples 6-1 and 6-2 were repeated to produce a GaAs compound semiconductor solar cell not comprising the minute structure 50. The photoelectric conversion efficiency of the solar cell was found to be 5.5%.

### Example 7-1

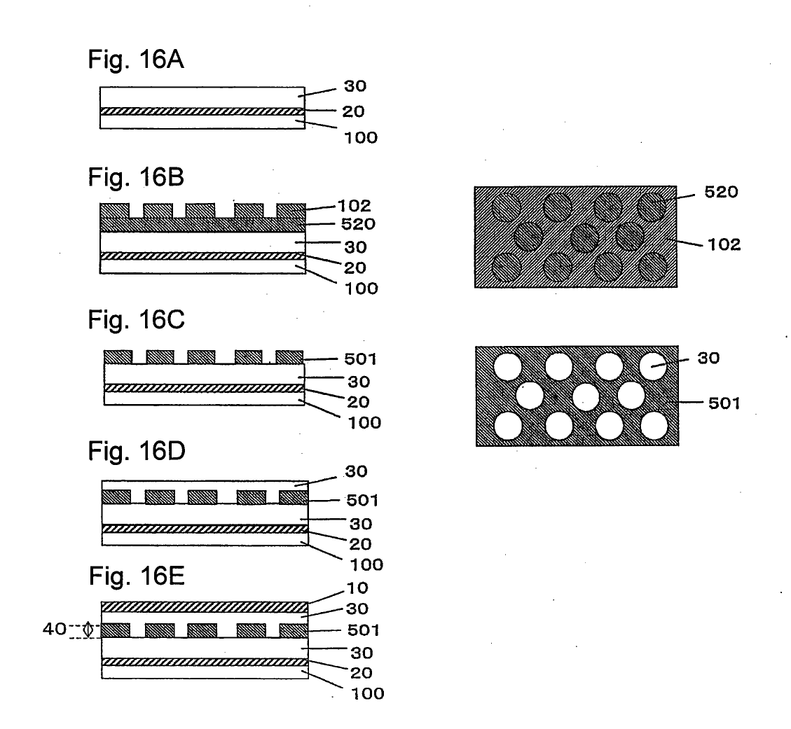

This example will explain a process of producing a chalcopyrite (CIGS) compound semiconductor solar cell having an electric field enhancing layer 40 provided with a porous membrane 501. This process will be described with reference to FIG. 16. In the present example, first a Mo electrode serving as the counter electrode 20 was formed on a soda-lime glass substrate 100 by vapor-deposition in vacuum. It is possible to use Ti and/or W as well as Ho for the counter electrode 20. Subsequently, Cu, In and Ga were deposited thereon by sputtering to form a layer referred to as “precursor”. The precursor was annealed at about 500° C. in a furnace under a H₂Se gas atmosphere, and was thereby converted into a CIGS layer 30 (FIG. 16(a)).

As the method for forming a photoelectric conversion layer 60, some techniques have been already developed. For example, Cu, In, Ga and Se are vapor-deposited to form a layer, which is then annealed. Accordingly, the embodiment of this example is not restricted by the above procedures and any method can be adopted to form a photoelectric conversion layer 60.

On the CIGS layer 30, an Au-made porous membrane 501 was formed in the same manner as in Example 4-1. Specifically, Au was vapor-deposited on the CIGS layer 30 to form an Au membrane 520 of 30 nm thickness, and then a resist pattern 102 provided with openings aligned periodically was formed thereon (left drawing of FIG. 16(b)). The right drawing of FIG. 16(b) is a plane view thereof seen from the side of the resist pattern 102. Similarly to Example 4-1, the Au membrane 520 was etched by use of the resist pattern 102 as a mask to form an Au-made porous membrane 501 (left drawing of FIG. 16(c)). The right drawing of FIG. 16(c) is a plane view thereof seen from the side of the porous membrane 501.

The Au-made porous membrane 501 thus formed had openings each of which had a diameter of 320 nm on average, and the average opening ratio was 37.0%.

On the Au-made porous membrane 501, a CdS layer 30 of 70 nm thickness was formed according to the solution growth method (FIG. 16(d)). In this procedure, the openings of the porous membrane 501 were filled with the CdS 30. Subsequently, a transparent electrode 10 of ZnO was formed on the CdS layer 30 by MOCVD to produce a solar cell (FIG. 16(e)).

The chalcopyrite compound semiconductor solar cell thus produced was evaluated in the same manner as in Example 1. As a result, it showed as good a photoelectric conversion efficiency as 7.1%. Further, the same procedures were repeated except for changing the material of the metal membrane 520 from Au into other metal, and as a result it was found that the conversion efficiency was 7.0%, 7.3% or 7.1% when the metal material was Al, Ag or Cu, respectively. Those results showed the effect of the present invention.

### Example 7-2

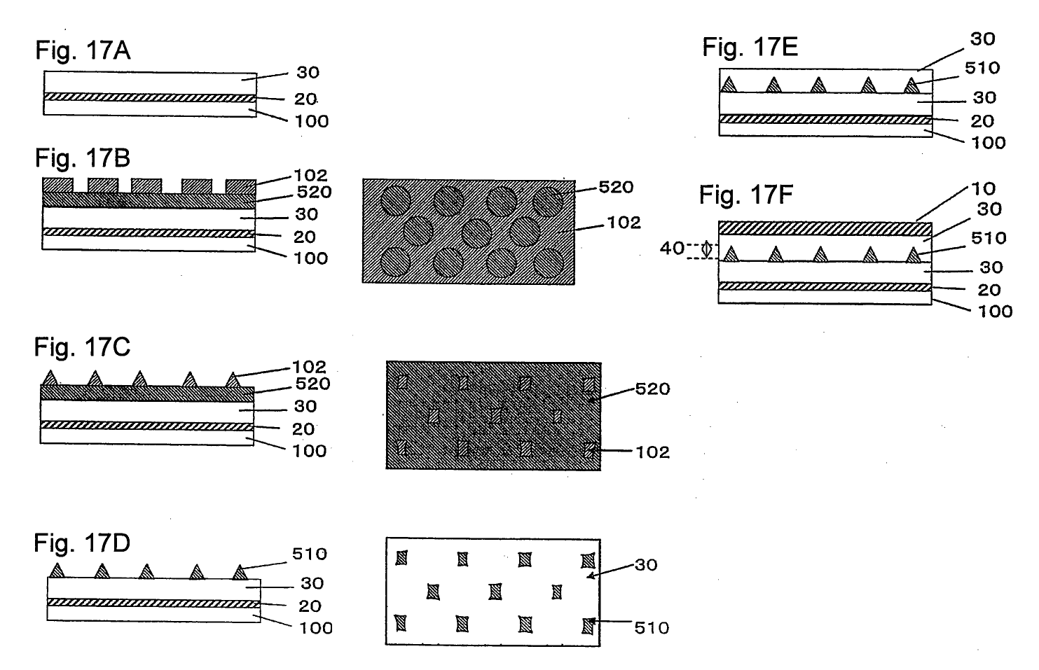

This example will explain a process of producing a chalcopyrite compound semiconductor solar cell having an electric field enhancing layer 40 provided with nano-objects 510. This process will be described with reference to FIG. 17. The nano-objects 510 were made of Au in the present example.

After a soda-lime glass substrate 100, a Mo electrode 10 and a CIGS layer 30 were prepared in the same manner as in Example 7-1 (FIG. 17(a)), an Au membrane 520 of 30 nm thickness was formed on the CIGS layer 30 by vapor deposition and then a resist pattern 102 provided with openings aligned periodically was formed in the same manner as in Example 4-1 (left drawing of FIG. 17(b)). The right drawing of FIG. 17(b) is a plane view thereof seen from the side of the resist pattern 102. Subsequently, the openings were extended by etching for 30 seconds according to RIE under the conditions of O₂: 5 sccm, Ar: 50 sccm, 0.7 Pa, 100 mTorr and a RF power of 100 W, to obtain a resist pattern 102 consisting of minute pyramidal objects (left drawing of FIG. 17(c)). The right drawing of FIG. 17(c) is a plane view thereof seen from the side of the resist pattern 102. The Au membrane 520 was etched by use of the obtained resist pattern 102 as a mask, to form Au-made pyramidal nano-objects 510 (left drawing of FIG. 17(d)). The right drawing of FIG. 17(d) is a plane view thereof seen from the side of the nano-objects 510.

Each of the nano-objects 510 thus formed had a volume of 6.2×10³ nm³ on average, and the center-to-center distance among them is 102 nm on average.

On the CIGS layer 30 provided with the Au-made nano-objects 510 thereon, a CdS layer 30 of 70 nm thickness was formed according to the solution growth method (FIG. 17(e)). Subsequently, a transparent electrode 10 of ZnO was formed on the CdS layer 30 by MOCVD to produce a solar cell (FIG. 17(f)).

The chalcopyrite compound semiconductor solar cell thus produced was evaluated in the same manner as in Example 1. As a result, it showed as good a photoelectric conversion efficiency as 7.0%. Further, the same procedures were repeated except for changing the material of the metal membrane 520 from Au into other metal, and as a result it was found that the conversion efficiency was 6.9%, 7.1% or 6.8% when the metal material was Al, Ag or Cu, respectively. Those results showed the effect of the present invention.

### Reference Example 7

The procedures of Examples 7-1 and 7-2 were repeated to produce a chalcopyrite compound semiconductor solar cell not comprising the minute structure 50. The photoelectric conversion efficiency of the solar cell was found to be 6.4%.

Needless to say, the above examples by no means restrict the present invention and hence can be variously modified.

Specifically, while certain embodiments have been described, these embodiments have been presented by way of example only, and are not intended to limit the scope of the invention. Indeed, the novel methods and systems described herein may be embodied in a variety of other forms; furthermore, various omissions, substitutions and changes in the form of the methods and systems described herein may be made without departing from the spirit of the invention. The accompanying claims and their equivalents are intended to cover such forms or modifications as would fall within the scope and sprit of the invention.

### BRIEF DESCRIPTION OF THE NUMERALS

10: light-incident side electrode

20: counter electrode

30: semiconductor layer

31: photoactive layer

32: bulk semiconductor layer

40: electric field enhancing layer

50: minute structure

60: photoelectric conversion layer

70: electron

71: hole

72: electron flow

V_{bi}: built-in electric field

100: substrate

102: resist layer

103: SOG layer

104: block co-polymer

105: microdomain

106a: composition containing acrylic monomers

106s: fine silica particle

501: porous membrane

502: minute sphere

503: minute pillar

504: minute cone

510: nano-object

520: metal membrane

530: end edge

p: semiconductor p-layer

i: semiconductor i-layer

n: semiconductor n-layer

701: electron oscillated by light

702: electron not oscillated

703: area where electrons are densely localized

704: area where electrons are thinly populated

705, 706: lower end part of minute structure

L: light

T: skin depth

E: local electric field

D: point at which local electric filed strength was calculated

1. A photoelectric conversion element comprising
a photoelectric conversion layer which comprises two electrode layers and two or more laminated semiconductor layers placed between said two electrode layers, and
a metal-made porous membrane placed between adjacent two of said semiconductor layers; wherein
said porous membrane has plural openings bored though said membrane;
each of said openings occupies an area of 80 nm² to 0.8 μm² inclusive on average, and
said porous membrane has a thickness of 2 nm to 200 nm inclusive.

2. The photoelectric conversion element according to claim 1, wherein each of said openings has a diameter of 10 nm to 1 μm inclusive on average.

3. The photoelectric conversion element according to claim 1, wherein adjacent two of said openings are separated by a metal area having a width of 10 nm to 1 μm inclusive on average.

4. A photoelectric conversion element comprising
a photoelectric conversion layer which comprises two electrode layers and two or more laminated semiconductor layers placed between said two electrode layers, and
a layer which has plural metal-made nano-objects and which is placed between adjacent two of said semiconductor layers; wherein
each of said nano-objects has a volume of 4 nm² to 0.52 μm³ inclusive on average, and
the average distance between adjacent two of said nano-objects is in the range of 1 nm to 1 μm inclusive.

5. A method of producing a photoelectric conversion element, comprising the steps of
forming a first semiconductor layer,
forming a metal membrane having a thickness of 2 nm to 200 nm inclusive on said first semiconductor layer;
forming a mask having a relief pattern,
forming, on said metal membrane by use of said mask, plural openings each of which occupies an area of 80 nm² to 0.8 μm² inclusive on average, and
forming a second semiconductor layer on said metal membrane provided with said openings according to said pattern.

6. A method of producing a photoelectric conversion element, comprising the steps of
forming a first semiconductor layer,
forming a metal membrane on said first semiconductor layer,
forming a mask having a relief pattern on said metal membrane,
forming, from said metal membrane by use of said mask, nano-objects each of which has a volume of 4 nm³ to 0.52 μm³ inclusive on average and adjacent two of which are separated by a distance of 1 nm to 1 μm inclusive on average, and
forming a second semiconductor layer on said nano-objects.

7. The method of producing a photoelectric conversion element, according to claim 5 or 6; wherein
the step of forming a mask includes the sub-step of forming a resist pattern on said metal membrane by use of a stamper.

8. The method of producing a photoelectric conversion element, according to claim 5 or 6; wherein
the step of forming a mask includes the sub-steps of
casting a resist on at least a part of said metal membrane or on at least a part of said first semiconductor layer, to form a resist coating layer,
forming a monolayer of fine particles on said resist coating layer, and
forming a fine relief pattern as a resist pattern by use of said monolayer as an etching mask.

9. The method of producing a photoelectric conversion element, according to claim 5 or 6; wherein
the step of forming a mask includes the sub-steps of forming an intermediate layer on at least a part of said metal membrane or on at least a part of said first semiconductor layer, and
forming microdomains of block copolymer on said intermediate layer.
